(19) United States
(12) Patent Application Publication
(10) Pub. No.: US 2026/0372203 A1
(43) Pub. Date: Nov. 19, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuo-Chiang Ting, Hsinchu City (TW); Sung-Feng Yeh, Taipei City (TW); Jian-Wei Hong, Hsinchu County (TW)

(73) Assignee: Taiwan Semiconductor Manufacturing Company, Ltd., Hsinchu (TW)

(21) Appl. No.: 19/754,222

(22) Filed: Jul. 26, 2026

Related U.S. Application Data
(62) Division of application No. 18/460,600, filed on Sep. 4, 2023.

(51) Int. Cl. H10W 90/00; H10W 72/20; H10W 74/10; H10W 80/00

(52) U.S. Cl. CPC H10W 90/00; H10W 74/117; H10W 72/252; H10W 80/312; H10W 80/327; H10W 90/792

(57) ABSTRACT

A semiconductor device includes a first die, a second die and a third die. The first die has a first side including a plurality of first connecting structures and a second side including a plurality of second connecting structures, where the first side is opposite to the second side. The second die has a third side including a plurality of third connecting structures, where the plurality of third connecting structures are in contact with the plurality of first connecting structures of the first die. The third die has a fourth side including a plurality of fourth connecting structures, where the plurality of fourth connecting structures are in contact with the plurality of second connecting structures of the first die. A first pitch of the plurality of first connecting structures and a second pitch of the plurality of third connecting structures are less than a third pitch of the plurality of fourth connecting structures.

### CROSS-REFERENCE TO RELATED APPLICATION

This application is a divisional application of U.S. application Ser. No. 18/460,600, filed on Sep. 4, 2023. The entirety of the above-mentioned patent application is hereby incorporated by reference herein and made a part of this specification.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 13 are schematic plane or cross-sectional views of various stages in a manufacturing method of a semiconductor device in accordance with some embodiments of the disclosure.

FIG. 14 is a schematic cross-sectional view showing a semiconductor device in accordance with alternative embodiments of the disclosure.

FIG. 15 is a schematic cross-sectional view showing a semiconductor device in accordance with alternative embodiments of the disclosure.

FIG. 16 to FIG. 18 are schematic plane or cross-sectional views of various stages in a manufacturing method of a semiconductor device in accordance with some embodiments of the disclosure.

FIG. 19 to FIG. 24 are schematic plane or cross-sectional views of various stages in a manufacturing method of a semiconductor device in accordance with some embodiments of the disclosure.

FIG. 25 is a schematic cross-sectional view showing a semiconductor device in accordance with some embodiments of the disclosure.

FIG. 26 is a schematic cross-sectional view showing a semiconductor device in accordance with alternative embodiments of the disclosure.

FIG. 27 is a schematic cross-sectional view showing a semiconductor device in accordance with alternative embodiments of the disclosure.

FIG. 28 to FIG. 30 are schematic plane or cross-sectional views of various stages in a manufacturing method of a semiconductor device in accordance with some embodiments of the disclosure.

FIG. 31 to FIG. 33 are schematic plane views of various embodiments of a semiconductor device in accordance with some embodiments of the disclosure.

FIG. 34 is a schematic cross-sectional view showing an application of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The specific embodiment(s) described herein is related to a semiconductor device (or a semiconductor package or structure) having a stacking structure of multi-tiers each including at least one semiconductor die or chip, and is not intended to limit the scope of the disclosure. Due to fine pitches of connecting structures formed on the semiconductor die or chip, the overall routing density is greatly improved, thereby obtaining higher performance and reduction in the manufacturing cost. Certain embodiments of the disclosure are related to a semiconductor device (or a semiconductor package or structure) having a stacking structure of multi-units each including multi-tiers stacked on one another, and each of the multi-tiers includes at least one semiconductor die or chip, where the multi-units are electrically independent (e.g., isolated) from one another or electrically communicated to each other. In embodiments of the disclosure, the semiconductor dies or chips of different tiers have different size in the occupied area, and/or the semiconductor dies or chips of the same tier have different size in the occupied area.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

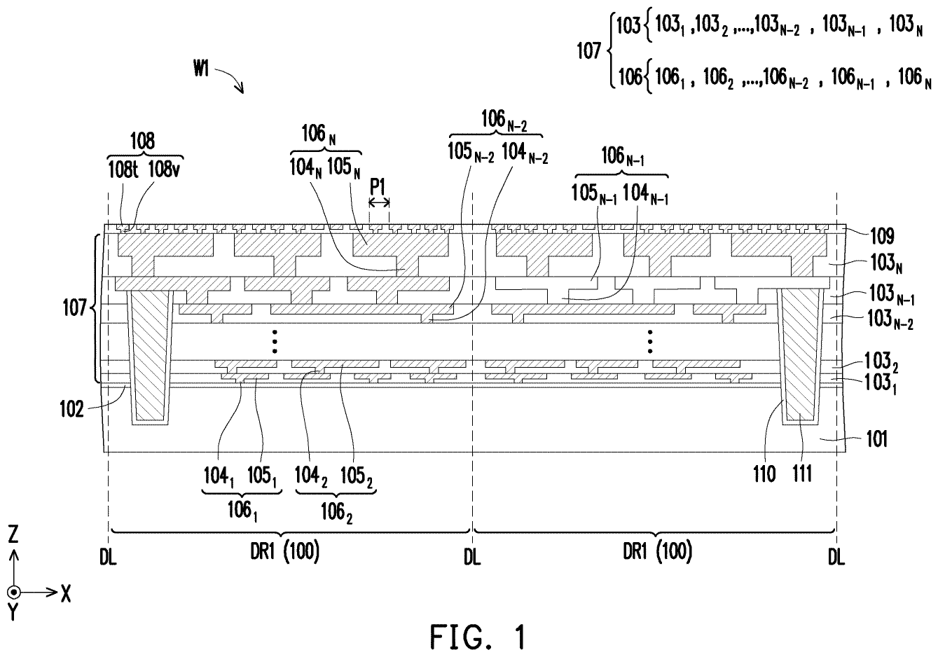

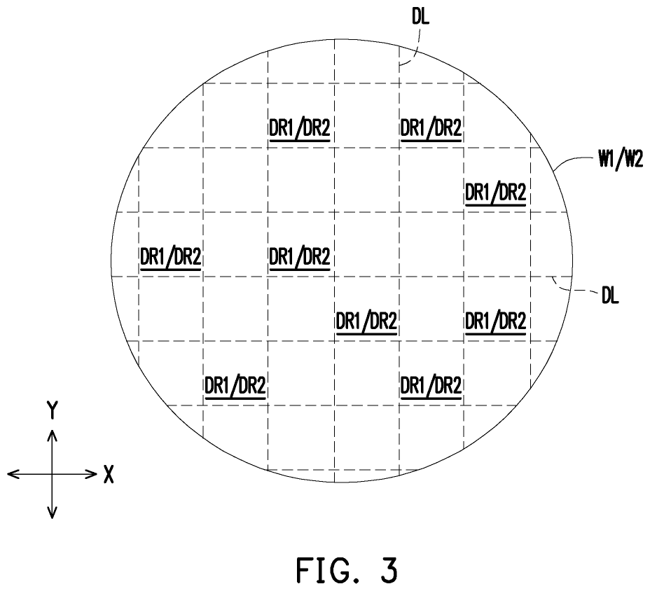

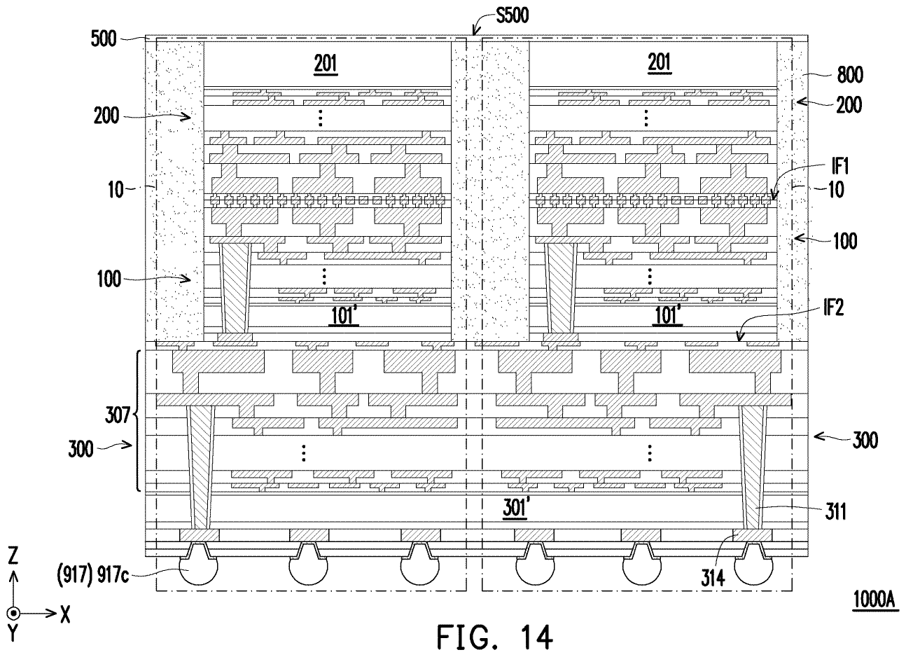

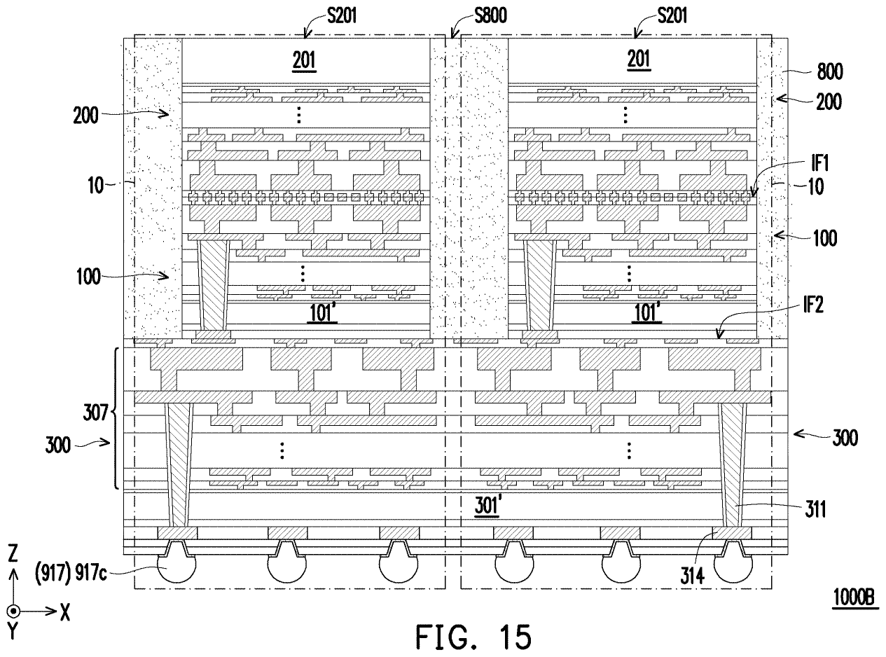

FIG. 1 to FIG. 13 are schematic plane or cross-sectional views of various stages in a manufacturing method of a semiconductor device 1000 in accordance with some embodiments of the disclosure, where the cross-sectional views of FIG. 1 through FIG. 2 and FIG. 4 through FIG. 13 are taken along a line A-A depicted in the plane view of FIG. 3. FIG. 14 is a schematic cross-sectional view showing a semiconductor device (e.g., 1000A) in accordance with alternative embodiments of the disclosure. FIG. 15 is a schematic cross-sectional view showing a semiconductor device (e.g., 1000B) in accordance with alternative embodiments of the disclosure. The embodiments are intended to provide further explanations but are not used to limit the scope of the disclosure.

Referring to FIG. 1, in some embodiments, a wafer W1 is provided. For example, the wafer W1 includes a wide variety of components (not shown) (also referred to as semiconductor components) formed therein. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure.

The wafer W1 may be a semiconductor wafer. In some embodiments, if considering a top or plane view (e.g., a X-Y plane) along a direction Z, the wafer W1 is in a wafer or panel form. In other words, the wafer W1 is processed in the form of a reconstructed wafer/panel. The wafer W1 may be in a form of wafer-size having a diameter of about 4 inches or more. The wafer W1 may be in a form of wafer-size having a diameter of about 6 inches or more. The wafer W1 may be in a form of wafer-size having a diameter of about 8 inches or more. Or alternatively, the wafer W1 may be in a form of wafer-size having a diameter of about 12 inches or more. In some embodiments, the wafer W1 includes a plurality of device regions DR1 arranged in a form of an array along a direction X and a direction Y, where each device region DR1 is a positioning (or pre-determined) location for a semiconductor die or chip (e.g., 100). The direction X, the direction Y and the direction Z may be different from each other. For example, the direction X is perpendicular to the direction Y, and the direction X and the direction Y are independently perpendicular to the direction Z, as shown in FIG. 1 and FIG. 3. In the disclosure, the direction Z may be referred to as a stacking direction, and the X-Y plane defined by the direction X and the direction Y may be referred to as the plane view or top view.

In addition, the semiconductor dies 100 of the wafer W1 being formed in different and individual device regions RD1 are electrically independent from (e.g., electrically isolated from) each other. The semiconductor dies 100 may be referred to as semiconductor dies or chips, independently, including a digital chip, an analog chip, or a mixed signal chip. In some embodiments, the semiconductor dies 100 are, independently, a logic die such as a central processing unit (CPU), a graphics processing unit (GPU), a neural network processing unit (NPU), a deep learning processing unit (DPU), a tensor processing unit (TPU), a system-on-a-chip (SoC), a system-on-integrated circuit (SoIC), an application processor (AP), and a microcontroller; a power management die such as a power management integrated circuit (PMIC) die; a wireless and radio frequency (RF) die; a baseband (BB) die; a sensor die such as a photo/image sensor chip; a micro-electro-mechanical-system (MEMS) die; a signal processing die such as a digital signal processing (DSP) die; a front-end die such as an analog front-end (AFE) dies; an application-specific die such as an application-specific integrated circuit (ASIC), a field-programmable gate array (FPGA); a combination thereof; or the like. In alternative embodiments, the semiconductor dies 100 are, independently, a memory die with a controller or without a controller, where the memory die includes a single-form die such as a dynamic random access memory (DRAM) die, a static random access memory (SRAM) die, a resistive random-access memory (RRAM), a magnetoresistive random-access memory (MRAM), a NAND flash memory, or a wide I/O (WIO) memory; a pre-stacked memory cube such as a hybrid memory cube (HMC) module, a high bandwidth memory (HBM) module; a combination thereof; or the like. In further alternative embodiments, the semiconductor dies 100 are, independently, an artificial intelligence (AI) engine such as an AI accelerator; a computing system such as an AI server, a high-performance computing (HPC) system, a high power computing device, a cloud computing system, a networking system, an edge computing system, a immersive memory computing system (ImMC), a SoIC system, etc. ; a combination thereof; or the like. In some other embodiments, the semiconductor dies 100 are, independently, an electrical and/or optical input/output (I/O) interface die, an integrated passives die (IPD), a voltage regulator die (VR), a local silicon interconnect die (LSI) with or without deep trench capacitor (DTC) features, a local silicon interconnect die with multi-tier functions such as electrical and/or optical network circuit interfaces, IPD, VR, DTC, or the like. The types of the semiconductor dies 100 may be selected and designated based on the demand and design requirement, and thus are not specifically limited in the disclosure.

In some embodiments, the types of all of the semiconductor dies 100 are identical. In alternative embodiments, the types of some of the semiconductor dies 100 are different from each other, while the types of some of the semiconductor dies 100 are identical types. In further alternative embodiments, the types of all of the semiconductor dies 100 are different. In some embodiments, the sizes of all of the semiconductor dies 100 are the same. In alterative embodiments, the sizes of some of the semiconductor dies 100 are different from each other, while the sizes of some of the semiconductor dies 100 are the same sizes. In further alternative embodiments, the sizes of all of the semiconductor dies 100 are different. In some embodiments, the shapes of all of the semiconductor dies 100 are identical. In alternative embodiments, the shapes of some of the semiconductor dies 100 are different from each other, while the shapes of some of the semiconductor dies 100 are identical. In further alternative embodiments, the shapes of all of the semiconductor dies 100 are different. The types, sizes and shapes of each of the semiconductor dies 100 are independent from each other, and may be selected and designed based on the demand and design layout, the disclosure is not limited thereto.

Before a wafer sawing or dicing process along scribe or dicing lines CL (shown as dotted lines in the illustrations) is performed on the wafer W1, the device regions DR1 of the wafer W1 are physically connected to one another, as shown in FIG. 1 and FIG. 3, for example. In FIG. 1 and FIGS. 4-6, only two device regions DR1 being included in the wafer W1 are shown for illustrative purposes, however the disclosure is not limited thereto. The number of the device regions DR1 may be more than two. As shown in FIG. 1, the wafer W1 may include a substrate 101, a device layer 102 disposed on the substrate 101, an interconnect 107 disposed on and electrically coupled to the device layer 102, a plurality of connecting structures 108 disposed on and electrically coupled to the interconnect 107, and a plurality of through vias 111 embedded in and electrically coupled to the interconnect 107 and further extended into the substrate 101.

In some embodiments, the substrate 101 includes a bulk semiconductor substrate, a crystalline silicon substrate, a doped semiconductor substrate (e.g., p-type semiconductor substrate or n-type semiconductor substrate), a semiconductor-on-insulator (SOI) substrate, or the like. In certain embodiments, the substrate 101 includes one or more doped regions or various types of doped regions, depending on design requirements. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. The substrate 101 may be a silicon wafer. Generally, the SOI substrate is a layer of a semiconductor material formed on an insulator layer. The insulator layer is, for example, a buried oxide (BOX) layer, a silicon oxide layer, or the like. Other substrates, such as a multi-layered or a gradient substrate, may also be used. In some alternative embodiments, the substrate 101 includes a semiconductor substrate made of an elemental semiconductor (such as diamond or germanium in a crystalline, a polycrystalline, or an amorphous structure, etc.); a compound semiconductor (such as gallium arsenide, silicon carbide, gallium phosphide, indium phosphide, indium arsenide and/or indium antimonide), an alloy semiconductor (such as silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc.), combinations thereof, or other suitable materials. For example, the substrate 101 is a silicon bulk substrate. The compound semiconductor substrate may have a multilayer structure, or may include a multilayer compound semiconductor structure. The alloy SiGe may be formed over a silicon substrate. The SiGe substrate may be strained.

The device layer 102 may be disposed over the substrate 101, and the components (not shown) formed therein may be or include active components, passive components, other suitable electrical components, and/or combinations thereof. In some embodiments, the components are formed in the device layer 102 disposed at a surface of the substrate 101 proximal to the interconnect 107, the components are formed in the device layer 102 disposed at a surface of the substrate 101 proximal to the interconnect 107 and further partially extended into the substrate 101, or a combination thereof. In some embodiments, as shown in FIG. 1, an illustrated top surface of the substrate 101 is referred to as an active surface or front-side of the substrate 101, and an illustrated bottom surface of the substrate 101 is referred to as an non-active surface or rear-side of the substrate 101, where the active surface or front-side of the substrate 101 is opposite to the non-active surface or rear-side of the substrate 101 along the direction Z, and the device layer 102 is overlaid on (e.g., in physical contact with) the active surface or front-side of the substrate 101. In some embodiments, the device layer 102 is interposed between the interconnect 107 and the substrate 101. The device layer 102 may include circuitry (not shown) formed in a front-end-of-line (FEOL) fabrication processes, and the interconnect 107 may be formed in a back-end-of-line (BEOL) fabrication processes.

In some embodiments, the interconnect 107 is disposed over the device layer 102, and the interconnect 107 is electrically coupled to the components formed in the device layer 102. That is, the interconnect 107 provides the routing functions to the components formed in the device layer 102. In some embodiments, at least some of the components formed in the device layer 102 are electrically communicated to one another by the interconnect 107. As shown in FIG. 1, the interconnect 107 may be overlaid over the device layer 102 and includes a plurality of build-up layers being electrically connecting there-between. As shown in FIG. 1, the interconnect 107 is formed on and electrically connected to the device layer 102, for example. In some embodiments, the interconnect 107 includes one or more dielectric layers 103 (e.g., 103₁, 103₂, . . . , 103_{N-2}, 103_{N-1}, and 103_{N}) and one or more patterned conductive layers 106 (e.g., 106₁, 106₂, . . . , 106_{N-2}, 106_{N-1}, and 106_{N}). In some embodiments, each patterned conductive layer 106 (e.g., 106₁, 106₂, . . . , 106_{N-2}, 106_{N-1}, and 106_{N}) includes a line portion 105 (e.g., 105₁, 105₂, . . . , 105_{N-2}, 105_{N-1}, and 105_{N}) extending along a horizontal direction (e.g., the direction X or the direction Y), a via portion 104 (e.g., 104₁, 104₂, . . . , 104_{N-2}, 104_{N-1}, and 104_{N}) extending along a vertical direction (e.g., the direction Z), and/or a combination thereof. The patterned conductive layers 106 may be referred to as metallization layers or redistribution layers of the interconnect 107 to provide routing functions, and may be collectively referred to as a routing structure of the interconnect 107. The dielectric layers 103 may be collectively referred to as a dielectric structure of the interconnect 107 to provide protection for the routing structure, the metallization layers or redistribution layers of the interconnect 107. In some embodiments, in the interconnect 107, the dielectric layers (e.g., 103) and the patterned conductive layers (e.g., 106) are arranged in alternation. One dielectric layer and a respective one metallization layer together may be considered as one build-up layer (e.g., 103₁ and 106₁; 103₂ and 106₂; 103_{N-2} and 106_{N-2}; 103_{N-1} and 106_{N-1}; 103_{N} and 106_{N}; or the like) of the interconnect 107. As shown in FIG. 1, for example, a topmost layer (e.g., 106_{N}) of the patterned conductive layers 106 may be accessibly revealed by a topmost layer (e.g., 103_{N}) of the dielectric layers 103 for external connection. In the disclosure, the numbers of layers of the dielectric layers 103 and the patterned conductive layers 106 are not limited to what is depicted in FIG. 1, and may be selected and designated based on the demand and design layout. That is, the number (e.g., N) of layers of the dielectric layers (e.g., 103) and the patterned conductive layers (e.g., 106) can be one or greater than one. In some embodiments, line dimensions (e.g., thickness and width) of the patterned conductive layers 106 are gradually increased along a direction from the substrate 101 to the connecting structures 108.

In addition, one or more seed layers (not shown) may be included in the interconnect 107 to facilitate the formation of the patterned conductive layers 106, where the seed layers may be interposed between the patterned conductive layers 106 and the dielectric layers 103. In embodiment of which the seed layers are included, one patterned conductive layer 106 and a respective one seed layer (not shown) may be together referred to as a metallization layer or a redistribution layer of the interconnect 107 to provide routing functions. That is, with such embodiments, one patterned conductive layer 106 and a respective one seed layer (not shown) may be collectively referred to as a routing structure of the interconnect 107.

In some embodiments, the interconnect 107 may be formed by, but not limited to, forming a blanket layer of first dielectric material over the device layer 102; patterning the first dielectric material blanket layer to form a dielectric layer 103₁ having a plurality of first openings (not labeled) penetrating there-through and accessibly revealing portions of the device layer 102; optionally forming a blanket layer of first seed layer material over the dielectric layer 103₁, the first seed layer material blanket layer extending into the first openings to line the first openings and in contact with the exposed portions of the device layer 102; forming a blanket layer of a first conductive material over the first seed layer material blanket layer; patterning the first conductive material blanket layer to form a patterned conductive layer 106₁; using the patterned conductive layer 106₁ as etching mask to pattern the first seed layer material blanket layer and form a first respective seed layer, thereby forming one build-up layer (e.g., a first build-up layer including 103₁ and 106₁); forming a blanket layer of second dielectric material over the patterned conductive layer 106₁, the dielectric layer 103₁ and the first respective seed layer (if any); patterning the second dielectric material blanket layer to form a dielectric layer 103₂ having a plurality of second openings (not labeled) penetrating there-through and accessibly revealing portions of an illustrated top surface of the patterned conductive layer 106₁; optionally forming a blanket layer of second seed layer material over the dielectric layer 103₂, the second seed layer material blanket layer extending into the second openings to line the second openings and in contact with the exposed portions of the patterned conductive layer 106₁; forming a blanket layer of a second conductive material over the second seed layer material blanket layer; patterning the second conductive material blanket layer to form a patterned conductive layer 106₂; using the patterned conductive layer 106₂ as etching mask to pattern the second seed layer material blanket layer and form a second respective seed layer, thereby forming another build-up layer (e.g., a second build-up layer including 103₂ and 106₂); then repeating the formation steps of forming the first and/or second build-up layers to form the rest of build-up layers (e.g., a third build-up layer, a fourth build-up layer, . . . , a (N-2)^{th} build-up layer (e.g., including 103_{N-2} and 106_{N-2}), a (N-1)^{th} build-up layer (e.g., including 103_{N-1} and 106_{N-1}), and a (N)^{th} build-up layer (e.g., including 103_{N} and 106_{N}). Upon this, the interconnect 107 is manufactured. The interconnect 107 may be formed on the device layer 102 by single or dual damascene process. The disclosure is not limited thereto.

The material of each of the dielectric layers 103 (e.g., 103₁, 103₂, . . . , 103_{N-2}, 103_{N-1} and 103N) may be polyimide (PI), polybenzoxazole (PBO), benzocyclobutene (BCB), a nitride such as silicon nitride, an oxide such as silicon oxide, phosphosilicate glass (PSG), borosilicate glass (BSG), borophosphosilicate glass (BPSG), a combination thereof or the like, which may be patterned using a photolithography and/or etching process. The etching process may include a dry etching, a wet etching, or a combination thereof. The dielectric material blanket layer used to form the dielectric layers 103 (e.g., 103₁, 103₂, . . . , 103_{N-2}, 103_{N-1}, and 103_{N}) may be formed by suitable fabrication techniques such as spin-on coating, chemical vapor deposition (CVD) (e.g., plasma-enhanced chemical vapor deposition (PECVD)), or the like. In one embodiment, the materials of the dielectric layers 103 (e.g., 103₁, 103₂, . . . , 103_{N-2}, 103_{N-1}, and 103_{N}) are the same to each other. Alternatively, the materials of the dielectric layers 103 (e.g., 103₁, 103₂, . . . , 103_{N-2}, 103_{N-1}, and 103_{N}) may be different to one another, in part or all.

The optional seed layers individually are referred to as a metal layer, which can be a single layer or a composite layer including a plurality of sub-layers formed of different materials. For example, the optional seed layers each may be or include a titanium layer and a copper layer over the titanium layer. The seed layer material blanket layers used to form the optional seed layers may be formed in a manner of a blanket layer made of metal or metal alloy materials, the disclosure is not limited thereto. The material of each of the optional seed layers material blanket layers may include titanium, copper, molybdenum, tungsten, titanium nitride, titanium tungsten, combinations thereof, or the like, which may be formed using, for example, sputtering, physical vapor deposition (PVD), or the like. The seed layer material blanket layers may be patterned by etching, such as a dry etching process, a wet etching process, or a combination thereof; the disclosure is not limited thereto. In one embodiment, the materials of the optional seed layers are the same to each other. Alternatively, the materials of the optional seed layers may be different to one another.

The material of each of the conductive material blanket layers for forming the patterned conductive layers 106 (e.g., 106₁, 106₂, . . . , 106_{N-2}, 106_{N-1}, and 106_{N}) may be made of conductive materials formed by electroplating or deposition, such as copper, copper alloy, aluminum, aluminum alloy, or combinations thereof, which may be patterned to form a plurality of conductive patterns/segments using a photolithography and etching process. In some embodiments, the conductive patterns/segments each includes the line portion 105 (e.g., 105₁, 105₂, . . . , 105_{N-2}, 105_{N-1}, and 105_{N}) extending along a horizontal direction (e.g., the direction X and/or Y) and/or the line portion 105 (e.g., 105₁, 105₂, . . . , 105_{N-2}, 105_{N-1}, and 105_{N}) extending along the horizontal direction (e.g., the direction X and/or Y) in addition to the via portion 104 (e.g., 104₁, 104₂, . . . , 104_{N-2}, 104_{N-1}, and 104_{N}) connecting to the line portion 105 (e.g., 105₁, 105₂, . . . , 105_{N-2}, 105_{N-1}, and 105_{N}) and extending along a vertical direction (e.g., the direction Z). In one embodiment, the materials of the patterned conductive layers 106 (e.g., 106₁, 106₂, . . . , 106_{N-2}, 106_{N-1}, and 106_{N}) are the same to each other. Alternatively, the materials of the patterned conductive layers 106 (e.g., 106₁, 106₂, . . . , 106_{N-2}, 106_{N-1}, and 106_{N}) may be different to one another. In addition, the line portions 105 (e.g., 105₁, 105₂, . . . , 105_{N-2}, 105_{N-1}, and 105_{N}) may be referred to as conductive lines, conductive traces, conductive trenches, metallization lines, routing lines or redistribution lines, and the via portions 104 (e.g., 104₁, 104₂, . . . , 104_{N-2}, 104_{N-1}, and 104_{N})) may be referred to as conductive vias, metallization vias, routing vias or redistribution vias.

After forming the build-up layers of the interconnect 107, a dielectric layer 109 and the connecting structures 108 are formed over the dielectric layer 103_{N} and the patterned conductive layer 106_{N}, for example. That is, the wafer W1 further include the dielectric layer 109. In some embodiments, the connecting structures 108 are electrically connected to the patterned conductive layer 106_{N} exposed by the dielectric layer 103_{N}. In some embodiments, each connecting structure 108 includes a line portion 108t extending along the horizontal direction (e.g., the direction X or the direction Y), a via portion108v extending along the vertical direction (e.g., the direction Z), and/or a combination thereof. The formation and material of the dielectric layer 109 are similar to or substantially identical to the formation and material of the dielectric layer 103, the formation and material of the connecting structures 108 (including 108t and 108v) are similar to or substantially identical to the formation and material of the patterned conductive layer 106 (including 105 and 104), and thus are not repeated herein.

For example, as shown in FIG. 1, the connecting structures 108 penetrate through and are laterally covered by the dielectric layer 109, where illustrated top surfaces of the connecting structures 108 are accessibly revealed by the dielectric layer 109. The connecting structures 108 and the dielectric layer 109 may together be referred to as a bonding structure or a connecting layer of the wafer W1. In some embodiments, the illustrated top surfaces of the connecting structures 108 are substantially level with an illustrated top surface of the dielectric layer 109. In other words, the illustrated top surfaces of the connecting structures 108 are substantially coplanar with the illustrated top surface of the dielectric layer 109. A seed layer (not shown) may be formed before forming the connecting structures 108 and after the formation of the dielectric layer 109 so to facilitate the formation of the connecting structures 108. The formation and material of the optional seed layer have been previously described above, and thus are not repeated herein for brevity. In some embodiments, the material of the dielectric layer 109 is different from the materials of one or more of the dielectric layers 103. In certain embodiments, the material of the dielectric layer 109 is the same as the materials of the dielectric layers 103.

A pitch P1 between two immediately adjacent connecting structures 108 is less than 1 μm and greater than 0 μm, in some embodiments. The pitch P1 may be greater than 0 μm and may be less than or substantially equal to 0.95 μm or less, 0.90 μm or less, 0.85 μm or less, 0.80 μm or less, 0.75 μm or less, 0.70 μm or less, 0.65 μm or less, 0.60 μm or less, 0.55 μm or less, 0.50 μm or less, 0.45 μm or less, 0.40 μm or less, 0.35 μm or less, 0.30 μm or less, 0.25 μm or less, 0.20 μm or less, 0.15 μm or less, 0.10 μm or less, or so on.

In some embodiments, the through vias 111 are formed in the wafer W1 and extending from the interconnect 107 toward to a position inside the substrate 101. For example, the through vias 111 are electrically coupled to the interconnect 107 by direct contact between the patterned conductive layer 106_{N-1} (e.g., 105_{N-1}) and the through vias 111 (e.g., illustrated top surfaces thereof). The wafer W1 may further include a plurality of liners 110 to line sidewalls and illustrated bottom surfaces of the through vias 111. In some embodiments, each of the through vias 111 is covered by a respective liner 110. For example, the liners 110 are formed between the through vias 111 and the substrate 101, between the through vias 111 and the device layer 102, and between the through vias 111 and a part of the interconnect 107. In some embodiments, the through vias 111 may be tapered from the interconnect 107 to the substrate 101. Alternatively, the through vias 111 have substantially vertical sidewalls. In a cross-sectional view along the direction Z, the shape of the through vias 111 may depend on the design requirements, and is not intended to be limiting in the disclosure. On the other hand, in the top (plane) view on the X-Y plane, the shape of the through vias 111 is circular shape. However, depending on the design requirements, and the shape of the through vias 111 may be an oval shape, a rectangular shape, a polygonal shape, or combinations thereof; the disclosure is not limited thereto. In some embodiments, the liners 110 are not accessibly revealed by the rear surface of the substrate 101.

The through vias 111 may be formed of a conductive material, such as copper, tungsten, aluminum, silver, combinations thereof, or the like. The number of the through vias 111 is not limited in the disclosure, and may be selected and designated based on demand and design layout. The liners 110 may be formed of a barrier material, such as TiN, Ta, TaN, Ti, or the like. In alternative embodiments, a dielectric liner (not shown) (e.g., silicon nitride, an oxide, a polymer, a combination thereof, etc.) may be further optionally formed between the liners 110 and the substrate 101, between the liners 110 and the device layer 102, and between the liners 110 and a part of the interconnect 107. Alternatively, the liners 110 may be omitted.

The through vias 111, the liners 110 and the optional dielectric liners may be formed by, but not limited to, forming a plurality of recesses in the interconnect 107 right before forming the patterned conductive layer 106_{N-1} of the (N-1)^{th} build-up layer of the interconnect 107; respectively depositing the optional dielectric material, the barrier material and the conductive material in the recesses; and removing excess materials on an plane where illustrated openings of the recesses located at. For example, the recesses are lined with the optional dielectric liners so as to laterally separate the liners 110 lining the sidewalls and illustrated bottom surfaces of the through vias 111 from the substrate 101, the device layer 102 and a part of the interconnect 107. After the formation of through vias 111, the liners 110 and the optional dielectric liners, the rest of the components (e.g., 106_{N-1}, 103_{N}, and 106_{N}) of the interconnect 107 are then formed to manufacture the interconnect 107. The through vias 111 are formed by using a via-first approach, in some embodiments. In such embodiments, the through vias 111 are formed prior to the formation of the interconnect 107. Alternatively, the through vias 111 may be formed by using a via-last approach. In some embodiments, the through vias 111 are electrically coupled to the components formed in the device layer 102 through the interconnect 107. It is appreciated that, each device region RD1 is or includes one semiconductor die (or chip) 100.

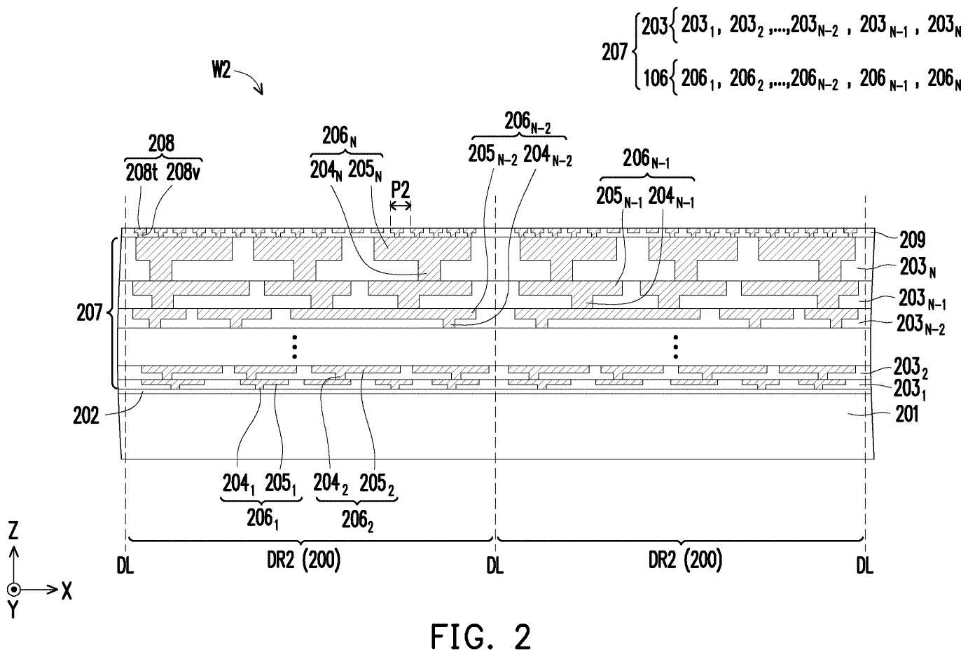

Referring to FIG. 2, in some embodiments, a wafer W2 is provided. For example, the wafer W2 includes a wide variety of components (not shown) (also referred to as semiconductor components) formed therein. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure. The wafer W2 may be a semiconductor wafer. In some embodiments, if considering the top or plane view (e.g., the X-Y plane) along the direction Z, the wafer W2 is in a wafer or panel form. In other words, the wafer W2 is processed in the form of a reconstructed wafer/panel. The wafer W2 may be in a form of wafer-size having a diameter of about 4 inches or more. The wafer W2 may be in a form of wafer-size having a diameter of about 6 inches or more. The wafer W2 may be in a form of wafer-size having a diameter of about 8 inches or more. Or alternatively, the wafer W2 may be in a form of wafer-size having a diameter of about 12 inches or more. In some embodiments, the wafer W2 includes a plurality of device regions DR2 arranged in a form of an array along the direction X and the direction Y, where each device region DR2 is a positioning (or pre-determined) location for a semiconductor die or chip (e.g., 200). In addition, the semiconductor dies 200 of the wafer W2 being formed in different and individual device regions RD2 are electrically independent from (e.g., electrically isolated from) each other.

Before a wafer sawing or dicing process along scribe or dicing lines CL (shown as dotted lines in the illustrations) is performed on the wafer W2, the device regions DR2 of the wafer W2 are physically connected to one another, as shown in FIG. 2 and FIG. 3, for example. In FIG. 2 and FIGS. 4-6, only two device regions DR2 being included in the wafer W2 are shown for illustrative purposes, however the disclosure is not limited thereto. The number of the device regions DR2 may be more than two. As shown in FIG. 2, the wafer W2 may include a substrate 201, a device layer 202 disposed on the substrate 201, an interconnect 207 (including one or more dielectric layers 203 (e.g., 203₁, 203₂, . . . , 203_{N-2}, 203_{N-1}, and 203_{N}) and one or more patterned conductive layers 206 (e.g., 206₁, 206₂, . . . , 206_{N-2}, 206_{N-1}, and 206_{N})) disposed on and electrically coupled to the device layer 202, a plurality of connecting structures 208 disposed on and electrically coupled to the interconnect 207, and a dielectric layer 209 laterally covering the connecting structures 208. In some embodiments, each patterned conductive layer 206 (e.g., 206₁, 206₂, . . . , 206_{N-2}, 206_{N-1}, and 206_{N}) includes a line portion 205 (e.g., 205₁, 205₂, . . . , 205_{N-2}, 205_{N-1}, and 205_{N}) extending along the horizontal direction (e.g., the direction X or the direction Y), a via portion 204 (e.g., 204₁, 204₂, . . . , 204_{N-2}, 204_{N-1}, and 204_{N}) extending along the vertical direction (e.g., the direction Z), and/or a combination thereof.

The patterned conductive layers 206 may be referred to as metallization layers or redistribution layers of the interconnect 207 to provide routing functions, and may be collectively referred to as a routing structure of the interconnect 207. The dielectric layers 203 may be collectively referred to as a dielectric structure of the interconnect 207 to provide protection for the routing structure, the metallization layers or redistribution layers of the interconnect 207. One dielectric layer and a respective one metallization layer together may be considered as one build-up layer (e.g., 203₁ and 206₁; 203₂ and 206₂; 203_{N-2} and 206_{N-2}; 203_{N-1} and 206_{N-1}; 203_{N} and 206_{N}; or the like) of the interconnect 207. In the disclosure, the numbers of layers of the dielectric layers 203 and the patterned conductive layers 206 are not limited to what is depicted in FIG. 2, and may be selected and designated based on the demand and design layout. That is, the number (e.g., N) of layers of the dielectric layers (e.g., 203) and the patterned conductive layers (e.g., 206) can be one or greater than one. In some embodiments, line dimensions (e.g., thickness and width) of the patterned conductive layers 206 are gradually increased along a direction from the substrate 201 to the connecting structures 208. In addition, one or more seed layers (not shown) may be included in the interconnect 207 to facilitate the formation of the patterned conductive layers 206. In embodiment of which the seed layers are included, one patterned conductive layer 206 and a respective one seed layer (not shown) may be together referred to as a metallization layer or a redistribution layer of the interconnect 207 to provide routing functions. That is, with such embodiments, one patterned conductive layer 206 and a respective one seed layer (not shown) may be collectively referred to as a routing structure of the interconnect 207. A pitch P2 between two immediately adjacent connecting structures 208 is less than 1 μm and greater than 0 μm, in some embodiments. The pitch P2 may be greater than 0 μm and may be less than or substantially equal to 0.95 μm or less, 0.90 μm or less, 0.85 μm or less, 0.80 μm or less, 0.75 μm or less, 0.70 μm or less, 0.65 μm or less, 0.60 μm or less, 0.55 μm or less, 0.50 μm or less, 0.45 μm or less, 0.40 μm or less, 0.35 μm or less, 0.30 μm or less, 0.25 μm or less, 0.20 μm or less, 0.15 μm or less, 0.10 μm or less, or so on. The details, formation and materials of each of the substrate 201, the device layer 202, the interconnect 207 (e.g., including 203 and 206 (including 204 and 205)), the connecting structures 208 (including line portions 208t and via portions 208v), the dielectric layer 209 and the optional seed layers are similar to or substantially identical to the details, formation and materials of each of the substrate 101, the device layer 102, the interconnect 107 (e.g., including 103 and 106 (including 104 and 105)), the connecting structures 108 (including 108t and 108v), the dielectric layer 109 and the optional seed layers as described in FIG. 1, and thus are not repeated herein for brevity. It is appreciated that, each device region RD2 is or includes one semiconductor die (or chip) 200.

In some embodiments, the types of all of the semiconductor dies 200 are identical. In alternative embodiments, the types of some of the semiconductor dies 200 are different from each other, while the types of some of the semiconductor dies 200 are identical types. In further alternative embodiments, the types of all of the semiconductor dies 200 are different. In some embodiments, the sizes of all of the semiconductor dies 200 are the same. In alterative embodiments, the sizes of some of the semiconductor dies 200 are different from each other, while the sizes of some of the semiconductor dies 200 are the same sizes. In further alternative embodiments, the sizes of all of the semiconductor dies 200 are different. In some embodiments, the shapes of all of the semiconductor dies 200 are identical. In alternative embodiments, the shapes of some of the semiconductor dies 200 are different from each other, while the shapes of some of the semiconductor dies 200 are identical. In further alternative embodiments, the shapes of all of the semiconductor dies 200 are different. The types, sizes and shapes of each of the semiconductor dies 200 are independent from each other, and may be selected and designed based on the demand and design layout, the disclosure is not limited thereto.

For a non-limiting example, the sizes of the semiconductor dies 200 included in the wafer W2 is different from (e.g., less than) the sizes of the semiconductor dies 100 included in the wafer W1. For another non-limiting example, the sizes of the semiconductor dies 200 included in the wafer W2 is different from (e.g., greater than) the sizes of the semiconductor dies 100 included in the wafer W1. For another non-limiting example, the sizes of the semiconductor dies 200 included in the wafer W2 are substantially equal to the sizes of the semiconductor dies 100 included in the wafer W1. Or alternatively, a combination of above conditions may be adopted.

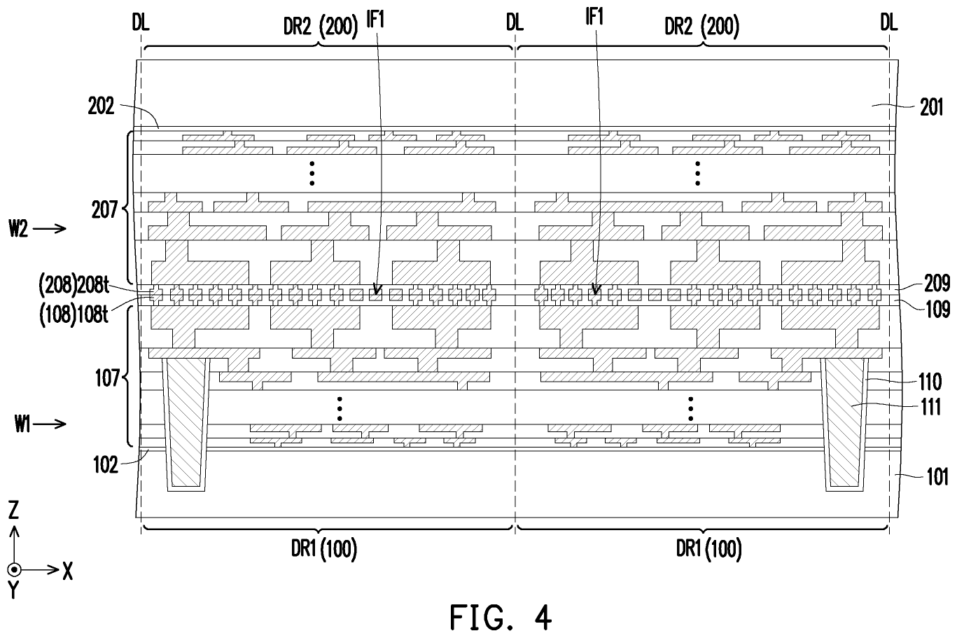

Referring to FIG. 4, in some embodiments, the wafer W2 is placed over and bonded to the wafer 1. For example, as shown in FIG. 4, each device region DR2 of the wafer W2 is arranged to be overlapped with a respective one device region DR1 of the wafer W1 in a vertical projection along the direction Z. In the case, in the cross-sectional view, the device regions DR2 of the wafer W2 and the device regions DR1 of the wafer W1 are overlapped with one another by a one-to-one configuration. In some embodiments, the wafer W2 is placed over the wafer W1 for bonding by pick-and-place process. In some embodiments, the wafer W2 is bonded to the wafer W1 by wafer-on-wafer (WoW) bonding.

For example, the wafer W2 is bonded to the wafer W1 by bonding process including both of a metal-to-metal bonding and a dielectric-to-dielectric bonding. For example, the wafer W2 is disposed on (e.g., in physical contact with) and electrically connected to the wafer W1. In some embodiments, as shown in FIG. 4, the connecting structures 208 of the wafer W2 and the connecting structures 108 of the wafer W1 prop against each other and are bonded together through direct metal-to-metal bonding (e.g., such as a ‘copper’-to-‘copper’ bonding). In addition, as shown in FIG. 4, the dielectric layer 209 of the wafer W2 and the dielectric layer 109 of the wafer W1 prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF1 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the wafer W2 and the wafer W1, and which is considered as a bonding interface of the wafer W2 and the wafer W1.

It should be noted that bonding methods described above are merely examples and are not intended to be limiting. An offset may present between sidewalls of the connecting structures 208 and sidewalls of the connecting structures 108 respectively underlying thereto. Since one of the connecting structures 208 and the connecting structures 108 may have a larger bonding surface than the other one, the direct metal-to-metal bonding may still be achieved even if misalignment occurs, thereby the reliability of electrical connections between the wafer W2 and the wafer W1 can be ensured. With such, for certain embodiments, either the dielectric layer 209 immediately adjacent to the connecting structures 208 is bonded to the connecting structures 108 (e.g., a ‘dielectric’-to-‘metal’ bonding), or the dielectric layer 109 immediately adjacent to the connecting structures 108 is bonded to the connecting structures 208 (e.g., a ‘dielectric’-to-‘metal’bonding).

In some embodiments, after bonding the wafer W1 and wafer W2, a stacking structure of wafer-form is formed. In such stacking structure of wafer-form, the semiconductor dies 200 of the wafer W2 are electrically connected and electrically communicated to the semiconductor dies 200 of the wafer W1, respectively. In addition, the semiconductor dies 200 of the wafer W2 being formed in different and individual device regions RD2 are electrically independent from (e.g., electrically isolated from) each other, and the semiconductor dies 100 of the wafer W1 being formed in different and individual device regions RD1 are electrically independent from (e.g., electrically isolated from) each other. Owing to the connecting structures 108 (with the pitches P1) and the connecting structures 208 (with the pitches P2), the overall routing density of the semiconductor device 1000 is greatly improved, thereby obtaining higher performance and reduced manufacturing cost.

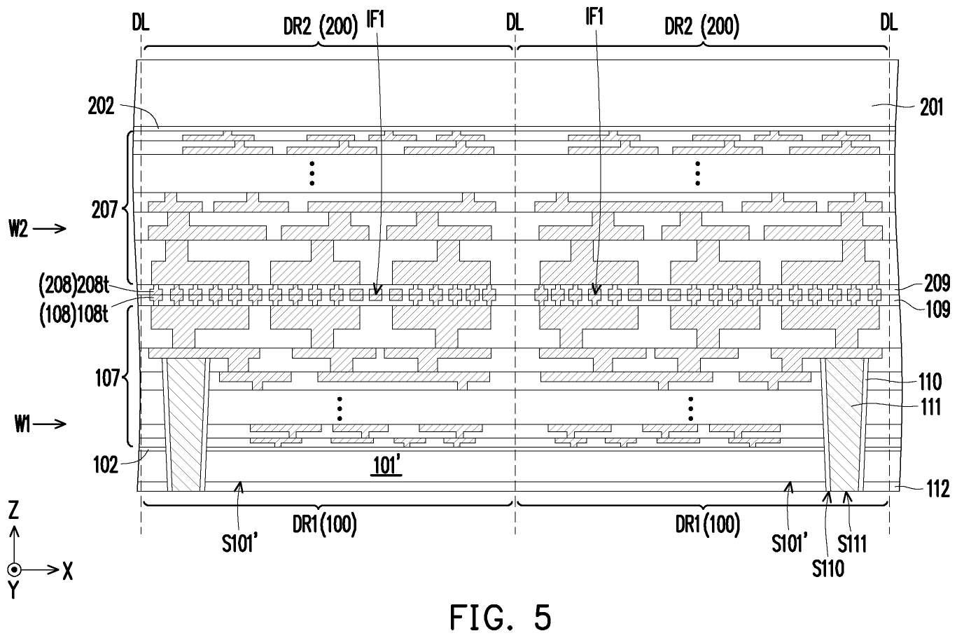

Referring to FIG. 5, in some embodiments, a first planarization process is performed to the substrate 101 so to thin down the substrate 101 and accessibly reveal the through vias 111. As shown in FIG. 5, a portion of the substrate 101 and portions of liners 110 are removed from the wafer W1 of the stacking structure so to expose the through vias 111 therefrom, for example. In some cases, during removing the portion of the substrate 101 and the portions of liners 110, portions of the through vias 111 may also be slightly removed. Then, a patterning process is performed on the substrate 101, where the substrate 101 is further partially removed to form a substrate 101′ having a patterned bottom surface S101′, such that a portion of each of the through vias 111 and a portion of each of the liners 110 protrude from the patterned bottom surface S101′ of the substrate 101′. The patterning process may include an etching process (such as a wet each or a dry etch) or the like, for example. The disclosure is not limited thereto. As shown in FIG. 5, the liners 110 may cover the entire sidewalls of the through vias 111; however the disclosure is not limited thereto. In one embodiment, the liners 110 may be cover only the sidewalls of the through vias 111 being embedded in the substrate 101′. That is, for example, the liners 110, which are disposed on the sidewalls of the portions of the through vias 111 protruding from the patterned bottom surface S101′ of the substrate 101′ after the first planarization process, are removed during the patterning process. The first planarization process may include a grinding process, a chemical mechanical polishing (CMP) process, an etching process, combination thereof, or the like. The etching process may include a dry etching, a wet etching, or a combination thereof.

In some embodiments, a dielectric material (not shown) is formed over the substrate 101′. In some embodiments, the dielectric material is directly formed on the substrate 101′, the through vias 111 and the liners 110, where the substrate 101′, the through vias 111 and the liners 110 are covered by and in physical contact with the dielectric material. In some embodiments, the dielectric material may be formed as a blanket layer of dielectric material. In some embodiments, the dielectric material may be a polymer layer which made of PI, PBO, BCB, or any other suitable polymer-based dielectric material. In some embodiments, the dielectric material may be Ajinomoto Buildup Film (ABF), Solder Resist (SR) film, or the like. In some embodiments, the dielectric material may be formed by a suitable fabrication technique such as spin-coating, lamination, deposition, or the like. Thereafter, a second planarization process is performed on the dielectric material to form a dielectric layer 112 laterally covering the through vias 111 and the liners 110, where the dielectric layer 112 exposes bottom surfaces S111 of the through vias 111 and bottoms surfaces S110 of the liners 110 and covers the patterned bottom surface S101′ of the substrate 101′. In some embodiments, during the second planarization process, the dielectric material laterally located next to the protruded portions of the through vias 111 over the patterned bottom surface S101′ of the substrate 101′ are remained, while the rest of the dielectric material are removed; and the remained dielectric material constitutes the dielectric layer 112. In some embodiments, the second planarization process may include a grinding process, a CMP process, an etching process, combination thereof, or the like. The etching process may include a dry etching, a wet etching, or a combination thereof. As shown in FIG. 5, a surface S112 of the dielectric layer 112 is substantially level with the bottom surfaces S111 of the through vias 111 and the bottoms surfaces S110 of the liners 110, for example. That is, the surface S112 of the dielectric layer 112 is substantially coplanar to the bottom surfaces S111 of the through vias 111 and the bottoms surfaces S110 of the liners 110.

In some embodiments, after the first and/or second planarization process, a cleaning step may be optionally performed to clean and remove the residue generated from the planarization process. However, the disclosure is not limited thereto, and the first and/or second planarization process may be performed through any other suitable method.

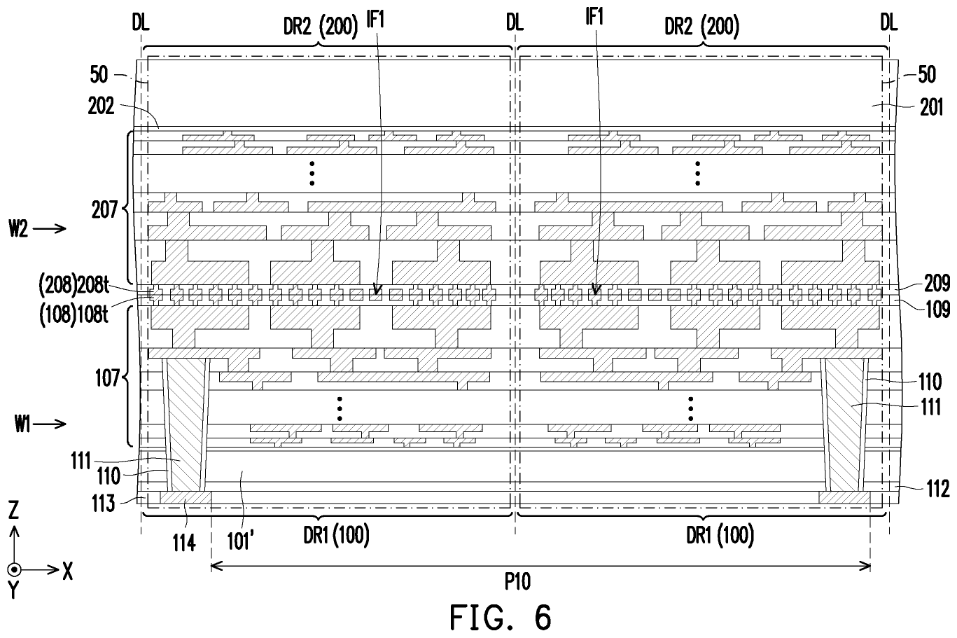

Referring to FIG. 6, in some embodiments, a dielectric layer 113 and a plurality of connecting structures 114 are formed over the wafer W1 of the stacking structure, where the connecting structures 114 are electrically coupled to the interconnect 107 by the through vias 111. Some of the connecting structures 114 may be electrically coupled to the components formed in device layers 102 through the through vias 111 and the interconnect 107, and some of the connecting structures 114 may be electrically coupled to the components formed in device layers 202 through the through vias 111, the interconnect 107A and the interconnect 207, as shown in FIG. 6. A pitch P10 between two immediately adjacent connecting structures 114 is greater than or substantially equal to 1 μm, in some embodiments. In some embodiments, the pitches P10 are greater than the pitches P1 and P2. The formation and material of each of the dielectric layer 113 and the connecting structures 114 may be similar to or substantially identical to the formation and material of each of the dielectric layer 103 and the patterned conductive layer 106 (e.g., 105) as previously discussed in FIG. 1, and thus are not repeated herein for brevity.

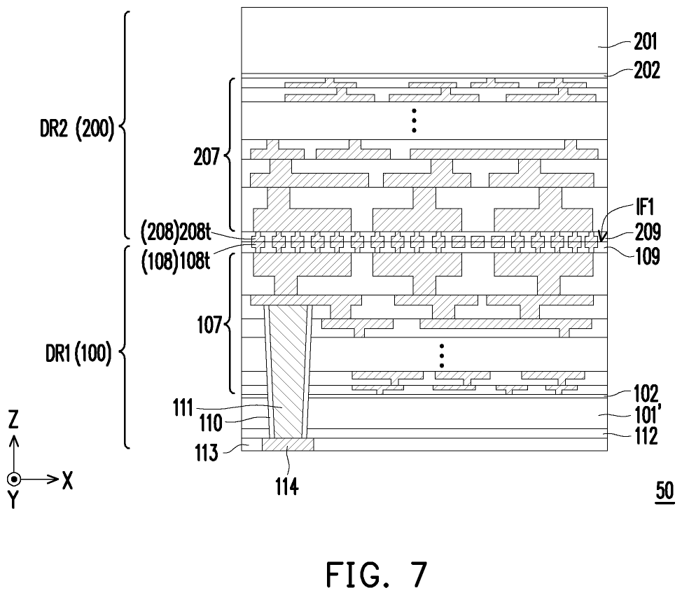

In some embodiments, a dicing (singulation) process is performed to cut the wafer W1 and the wafer W2 of the stacking structure so to form a plurality of stacking units 50. Referring to FIG. 7, only one stacking unit 50 is shown for illustrative purposes. In one embodiment, the dicing (singulation) process is a wafer dicing process including mechanical blade sawing or laser cutting. The disclosure is not limited thereto. In some embodiments, each stacking unit 50 includes one semiconductor die 100 (e.g., located in the device regions DR1 of the wafer W1) and one semiconductor die 200 (e.g., located in the device regions DR2 of the wafer W2) stacked thereon, where the semiconductor die 200 is electrically communicated and electrically connected to the semiconductor die 100 by connecting the connecting structures 208 and the connecting structures 108.

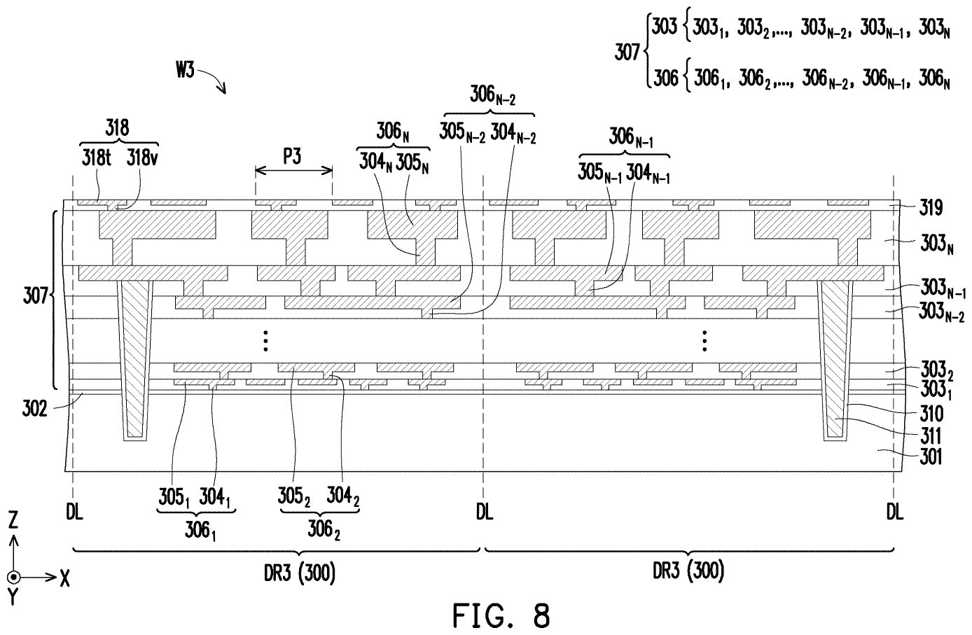

Referring to FIG. 8, in some embodiments, a wafer W3 is provided. For example, the wafer W3 includes a wide variety of components (not shown) (also referred to as semiconductor components) formed therein. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure. The wafer W3 may be a semiconductor wafer. In some embodiments, if considering the top or plane view (e.g., the X-Y plane) along the direction Z, the wafer W3 is in a wafer or panel form. In other words, the wafer W3 is processed in the form of a reconstructed wafer/panel. The wafer W3 may be in a form of wafer-size having a diameter of about 4 inches or more. The wafer W3 may be in a form of wafer-size having a diameter of about 6 inches or more. The wafer W3 may be in a form of wafer-size having a diameter of about 8 inches or more. Or alternatively, the wafer W3 may be in a form of wafer-size having a diameter of about 12 inches or more. In some embodiments, the wafer W3 includes a plurality of device regions DR3 arranged in a form of an array along the direction X and the direction Y, where each device region DR3 is a positioning (or pre-determined) location for a semiconductor die or chip (e.g., 300).

Before a wafer sawing or dicing process along scribe or dicing lines CL (shown as dotted lines in the illustrations) is performed on the wafer W3, the device regions DR3 of the wafer W3 are physically connected to one another, as shown in FIG. 8, for example. In FIG. 8-13, only two device regions DR3 being included in the wafer W3 are shown for illustrative purposes, however the disclosure is not limited thereto. The number of the device regions DR3 may be more than two. As shown in FIG. 8, the wafer W3 may include a substrate 301, a device layer 302 disposed on the substrate 301, an interconnect 307 (including one or more dielectric layers 303 (e.g., 303₁, 303₂, . . . , 303_{N-2}, 303_{N-1}, and 303_{N}) and one or more patterned conductive layers 306 (e.g., 306₁, 306₂, . . . , 306_{N-2}, 306_{N-1}, and 306_{N})) disposed on and electrically coupled to the device layer 302, a plurality of connecting structures 318 disposed on and electrically coupled to the interconnect 307, a dielectric layer 319 laterally covering the connecting structures 318, a plurality of through vias 311 embedded in and electrically coupled to the interconnect 307 and further extending into the substrate 301, and a plurality of liners 110 lining sidewalls and bottom surfaces of the through vias 311. In some embodiments, each patterned conductive layer 306 (e.g., 306₁, 306₂, . . . , 306_{N-2}, 306_{N-1}, and 306_{N}) includes a line portion 305 (e.g., 305₁, 305₂, . . . , 305_{N-2}, 305_{N-1}, and 305_{N}) extending along the horizontal direction (e.g., the direction X or the direction Y), a via portion 304 (e.g., 304₁, 304₂, . . . , 304_{N-2}, 304_{N-1}, and 304_{N}) extending along the vertical direction (e.g., the direction Z), and/or a combination thereof.

The patterned conductive layers 306 may be referred to as metallization layers or redistribution layers of the interconnect 307 to provide routing functions, and may be collectively referred to as a routing structure of the interconnect 307. The dielectric layers 303 may be collectively referred to as a dielectric structure of the interconnect 307 to provide protection for the routing structure, the metallization layers or redistribution layers of the interconnect 307. One dielectric layer and a respective one metallization layer together may be considered as one build-up layer (e.g., 303₁ and 306₁; 303₂ and 306₂; 303_{N-2} and 306_{N-2}; 303_{N-1} and 306_{N-1}; 303_{N} and 306_{N}; or the like) of the interconnect 307. In the disclosure, the numbers of layers of the dielectric layers 303 and the patterned conductive layers 306 are not limited to what is depicted in FIG. 8, and may be selected and designated based on the demand and design layout. That is, the number (e.g., N) of layers of the dielectric layers (e.g., 303) and the patterned conductive layers (e.g., 306) can be one or greater than one. In some embodiments, line dimensions (e.g., thickness and width) of the patterned conductive layers 306 are gradually increased along a direction from the substrate 301 to the connecting structures 318. In addition, one or more seed layers (not shown) may be included in the interconnect 307 to facilitate the formation of the patterned conductive layers 306. In embodiment of which the seed layers are included, one patterned conductive layer 306 and a respective one seed layer (not shown) may be together referred to as a metallization layer or a redistribution layer of the interconnect 307 to provide routing functions. That is, with such embodiments, one patterned conductive layer 306 and a respective one seed layer (not shown) may be collectively referred to as a routing structure of the interconnect 307. A pitch P3 between two immediately adjacent connecting structures 318 is greater than or substantially equal to 1 μm, in some embodiments. In some embodiments, the pitches P3 are greater than the pitches P1 and P2. On the other hand, the pitches P3 may be less than, greater than, or substantially equal to the pitches P10, the disclosure is not limited thereto. The number of the through vias 311 may be more than what is depicted in FIG. 8, and may be designed based on the demand and design requirement. The details, formation and materials of each of the substrate 301, the device layer 302, the interconnect 307 (e.g., including 303 and 306 (including 304 and 305)), the optional seed layers, the through vias 311 and the liners 310 are similar to or substantially identical to the details, formation and materials of each of the substrate 101, the device layer 102, the interconnect 107 (e.g., including 103 and 106 (including 104 and 105)), the optional seed layers, the through vias 111 and the liners 110 as previously described in FIG. 1, the formation and material of each of the dielectric layer 319 and the connecting structures 318 (including line portions 318t and via portions 318v) may be similar to or substantially identical to the formation and material of each of the dielectric layer 103 and the patterned conductive layer 106 (including 105 and 104) as previously discussed in FIG. 1, and thus are not repeated herein for brevity. It is appreciated that, each device region RD3 is or includes one semiconductor die (or chip) 300. In addition, the semiconductor dies 300 of the wafer W3 being formed in different and individual device regions RD3 are electrically independent from (e.g., electrically isolated from) each other.

In some embodiments, the types of all of the semiconductor dies 300 are identical. In alternative embodiments, the types of some of the semiconductor dies 300 are different from each other, while the types of some of the semiconductor dies 300 are identical types. In further alternative embodiments, the types of all of the semiconductor dies 300 are different. In some embodiments, the sizes of all of the semiconductor dies 300 are the same. In alterative embodiments, the sizes of some of the semiconductor dies 300 are different from each other, while the sizes of some of the semiconductor dies 300 are the same sizes. In further alternative embodiments, the sizes of all of the semiconductor dies 300 are different. In some embodiments, the shapes of all of the semiconductor dies 300 are identical. In alternative embodiments, the shapes of some of the semiconductor dies 300 are different from each other, while the shapes of some of the semiconductor dies 300 are identical. In further alternative embodiments, the shapes of all of the semiconductor dies 300 are different. The types, sizes and shapes of each of the semiconductor dies 300 are independent from each other, and may be selected and designed based on the demand and design layout, the disclosure is not limited thereto.

For a non-limiting example, the sizes of the semiconductor dies 300 included in the wafer W3 is different from (e.g., less than) the sizes of the semiconductor dies 100 included in the wafer W1. For another non-limiting example, the sizes of the semiconductor dies 300 included in the wafer W3 is different from (e.g., greater than) the sizes of the semiconductor dies 100 included in the wafer W1. For another non-limiting example, the sizes of the semiconductor dies 300 included in the wafer W3 are substantially equal to the sizes of the semiconductor dies 100 included in the wafer W1. Or alternatively, a combination of above conditions may be adopted.

For a non-limiting example, the sizes of the semiconductor dies 300 included in the wafer W3 is different from (e.g., less than) the sizes of the semiconductor dies 200 included in the wafer W2. For another non-limiting example, the sizes of the semiconductor dies 300 included in the wafer W3 is different from (e.g., greater than) the sizes of the semiconductor dies 200 included in the wafer W2. For another non-limiting example, the sizes of the semiconductor dies 300 included in the wafer W3 are substantially equal to the sizes of the semiconductor dies 200 included in the wafer W2. Or alternatively, a combination of above conditions may be adopted.

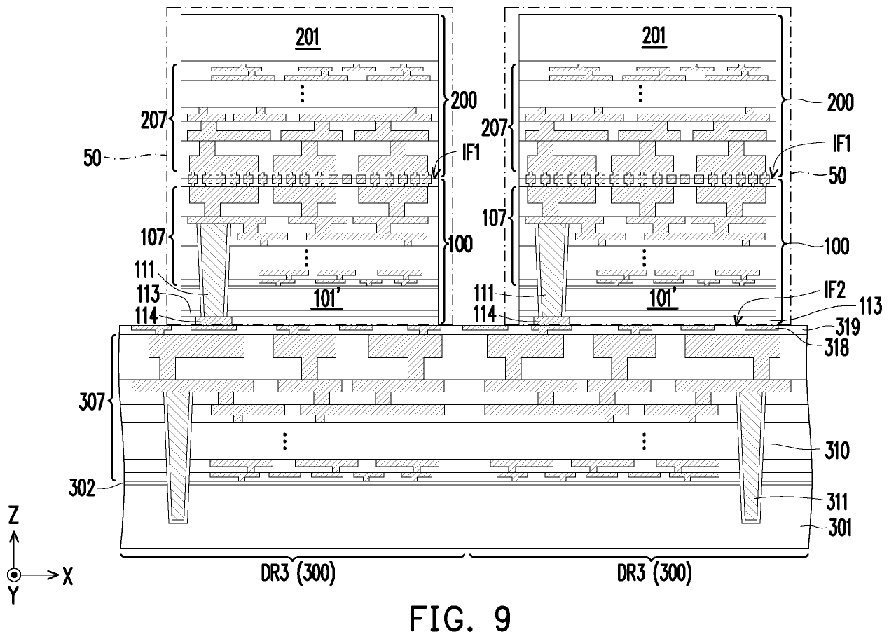

Referring to FIG. 9, in some embodiments, one or more stacking units 50 are picked and placed on the wafer W3. In some embodiments, the stacking units 50 are respectively arranged in the device regions DR3, as shown in FIG. 9. For illustrative purposes, only two stacking units 50 are shown in FIG. 9 for simplicity, however the disclosure is not limited thereto. The number of the stacking units 50 may be more than two. The number of the stacking units 50 may be selected and designated based on the demand or design layout. The number of the stacking units 50 may correspond to the number of the device regions DR3 included in the wafer W3. For one non-limiting example, the stacking units 50 are overlapped with the semiconductor dies 300 (e.g., located in the device regions DR3 of the wafer W3) in a manner of one-to-one configuration, in the direction Z, as shown in FIG. 9. For another non-limiting example, the stacking units 50 are overlapped with the semiconductor dies 300 (e.g., located in the device regions DR3 of the wafer W3) in a manner of plurality-to-one configuration (such as two-to-one configuration, three-to-one configuration, four-to-one configuration, five-to-one configuration, or the like), in the direction Z.

After the placement of the stacking units 50, a bonding process is performed to bond the stacking units 50 onto a respective one semiconductor die 300 of the wafer W3 overlapped therewith along the direction Z, in some embodiments. For example, the stacking units 50 are bonded to the wafer W3 by bonding process including both of a metal-to-metal bonding and a dielectric-to-dielectric bonding. For example, the stacking units 50 are disposed on (e.g., in physical contact with) and electrically connected to the wafer W3. In some embodiments, as shown in FIG. 9, the connecting structures 114 of the semiconductor dies 100 of the stacking units 50 and the connecting structures 318 (e.g., 318t) of the wafer W3 prop against each other and are bonded together through direct metal-to-metal bonding (e.g., such as a ‘copper’-to-‘copper’ bonding). In addition, as shown in FIG. 9, the dielectric layers 113 of the semiconductor dies 100 of the stacking units 50 and the dielectric layer 319 of the wafer W3 prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF2 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the stacking units 50 and the wafer W3, and which is considered as a bonding interface of the stacking units 50 and the wafer W3.

It should be noted that bonding methods described above are merely examples and are not intended to be limiting. An offset may present between sidewalls of the connecting structures 114 and sidewalls of the connecting structures 318 respectively underlying thereto. Since one of the connecting structures 114 and the connecting structures 318 may have a larger bonding surface than the other one, the direct metal-to-metal bonding may still be achieved even if misalignment occurs, thereby the reliability of electrical connections between the stacking units 50 and the wafer W3 can be ensured. With such, for certain embodiments, either the dielectric layer 113 immediately adjacent to the connecting structures 114 is bonded to the connecting structures 318 (e.g., a ‘dielectric’-to-‘metal’ bonding), or the dielectric layer 319 immediately adjacent to the connecting structures 318 is bonded to the connecting structures 114 (e.g., a ‘dielectric’-to-‘metal’ bonding). In the embodiments of which the stacking units 50 are overlapped with the semiconductor dies 300 (e.g., located in the device regions DR3 of the wafer W3) in a manner of one-to-one configuration, the single stacking unit 50 overlying each semiconductor die 300 is electrically independent from (e.g., electrically isolated from) from each other. In the embodiments of which the stacking units 50 are overlapped with the semiconductor dies 300 (e.g., located in the device regions DR3 of the wafer W3) in a manner of plurality-to-one configuration, the stacking units 50 overlying a respective one of the semiconductor dies 300 are electrically independent from (e.g., electrically isolated from) the stacking units 50 respectively overlying the rest of the semiconductor dies 300. In some embodiments, the stacking units 50 is bonded to the wafer W3 by chip-on-wafer (CoW) bonding.

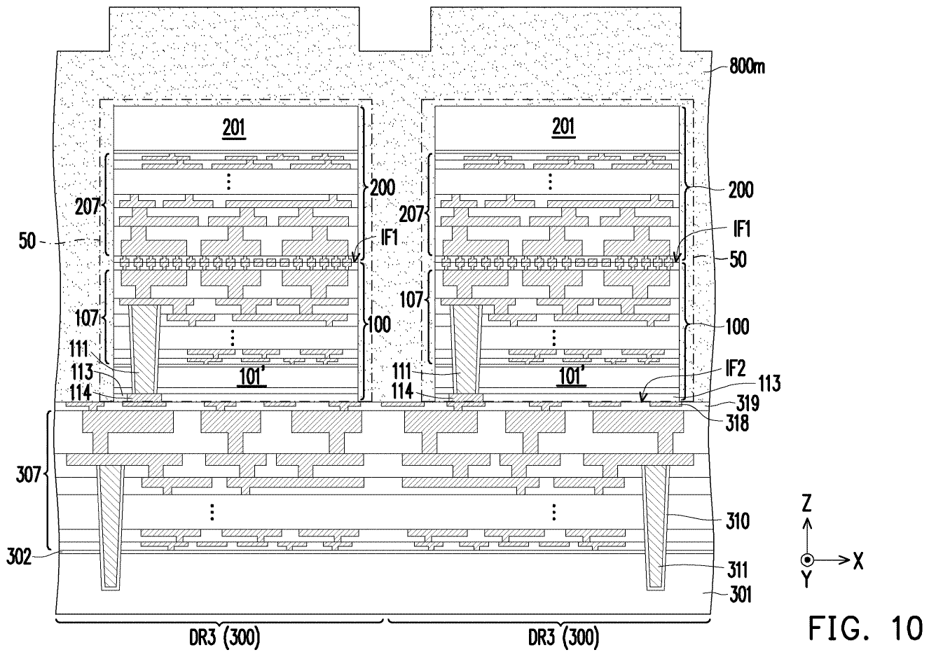

Referring to FIG. 10, in some embodiments, the stacking units 50 are encapsulated in an insulating material. In some embodiments, an insulating encapsulation 800m is conformally formed on the stacking units 50 and over the wafer W3, where the stacking units 50 and the wafer W3 exposed by the stacking units 50 are completely covered by the insulating encapsulation 800m. The insulating encapsulation 800m may be made of a dielectric material (such as an oxide (e.g., silicon oxide), a nitride (e.g., silicon nitride), tetra-ethyl-ortho-silicate (TEOS), or the like) or any suitable insulating materials for gap fill, and may be formed by deposition (such as a CVD process). As shown in FIG. 10, the stacking units 50 are not accessibly revealed by the insulating encapsulation 800m, for example.

Alternatively, the insulating encapsulation 800m may be a molding compound, a molding underfill, a resin (such as epoxy-based resin), or the like, which may be formed by a molding process. The molding process may include a compression molding process or a transfer molding process. The insulating encapsulation 800m may include polymers (such as epoxy resins, phenolic resins, silicon-containing resins, or other suitable resins) or other suitable materials. Alternatively, the insulating encapsulation 800m may include an acceptable insulating encapsulation material. In some embodiments, the insulating encapsulation 800m further includes inorganic filler or inorganic compound (e.g. silica, clay, and so on) which can be added therein to optimize coefficient of thermal expansion (CTE) of the insulating encapsulation 800m. The disclosure is not limited thereto.

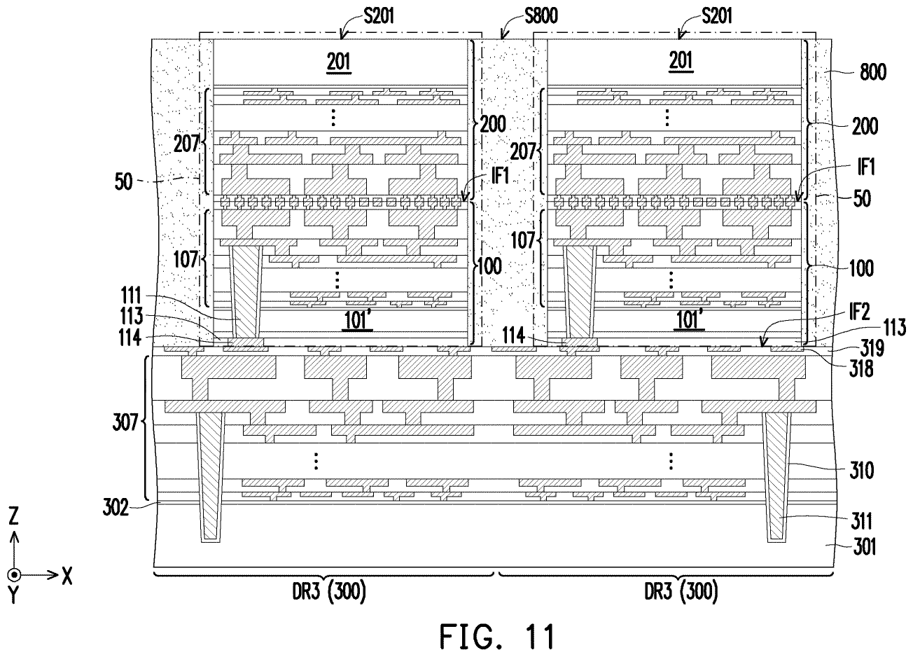

Referring to FIG. 10 and FIG. 11 together, in some embodiments, a third planarization process is performed on the insulating encapsulation 800m to form an insulating encapsulation 800 exposing the stacking units 50 (e.g., semiconductor dies 200). For example, a portion of the insulating encapsulation 800m is removed to form the insulating encapsulation 800 having an illustrated top surface S800, where the illustrated top surface S800 of the insulating encapsulation 800 accessibly reveals the semiconductor dies 200 (e.g., surfaces S201). For example, the illustrated top surface S800 of the insulating encapsulation 800 is substantially level with the surfaces S201 of the semiconductor dies 200 included in the stacking units 50. In other words, the illustrated top surface S800 of the insulating encapsulation 800 is substantially coplanar to the surfaces S201 of the semiconductor dies 200 included in the stacking units 50.

In some embodiments, after the third planarization process, a cleaning step may be optionally performed to clean and remove the residue generated from the third planarization process. However, the disclosure is not limited thereto, and the third planarization process may be performed through any other suitable method. In addition, during the third planarization process, a portion of each of the substrates 201 of the semiconductor dies 200 includes in the stacking units 50 may also be slightly removed. The disclosure is not limited thereto.

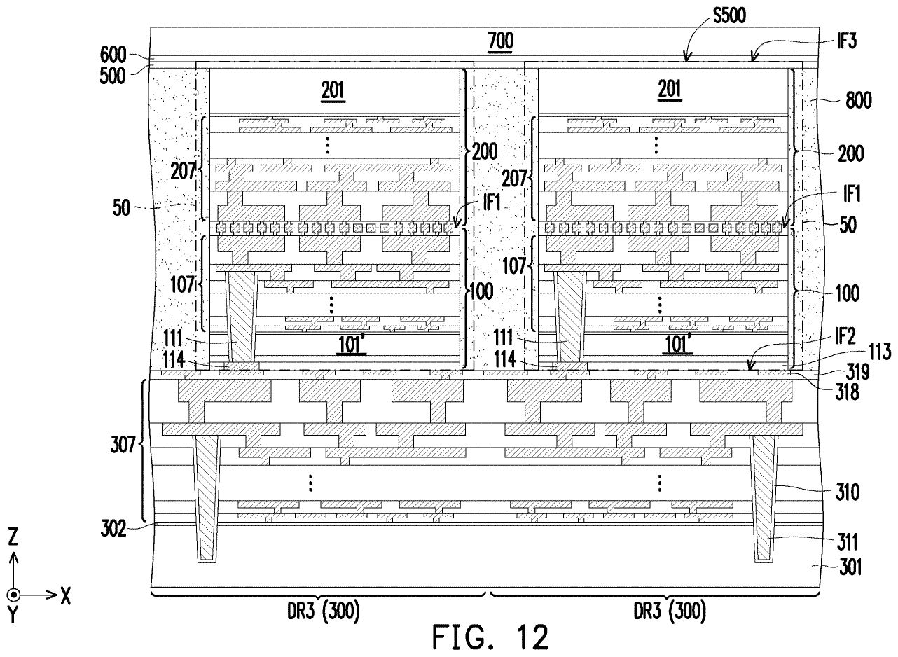

Referring to FIG. 12, in some embodiments, after the formation of the insulating encapsulation 800, a dielectric layer 500 is formed over the insulating encapsulation 800 and the stacking units 50 exposed by the insulating encapsulation 800. The dielectric layer 500 may be disposed on the insulating encapsulation 800 and the stacking units 50, and the insulating encapsulation 800 and the stacking units 50 may be disposed between the wafer W3 and the dielectric layer 500, as shown in FIG. 12. In some embodiments, the dielectric layer 500 is a blanket layer of dielectric material made of a nitride such as silicon nitride, an oxide such as silicon oxide, oxynitride such as silicon oxynitride, or the like. Alternatively, the dielectric layer 500 may be a polymer layer which made of PI, PBO, BCB, or any other suitable polymer-based dielectric material. Alternatively, the dielectric layer 500 may be ABF, SR film, or the like. As shown in FIG. 12, for example, an illustrated top surface S500 of the dielectric layer 500 may be level and may have a high degree of coplanarity. The dielectric layer 500 may be formed by a suitable fabrication technique such as spin-coating, lamination, deposition, or the like.

Continued on FIG. 12, in some embodiments, a carrier 700 coated with a dielectric layer 600 is bonded to the wafer W3 by a bonding process, where the dielectric layer 600 and the dielectric layer 500 are disposed between the carrier 700 and the wafer W3. The bonding process may include a dielectric-to-dielectric bonding. As shown in FIG. 9, the dielectric layer 600 formed on the carrier 700 and the dielectric layer 500 formed on of the insulating encapsulation 800 and the semiconductor dies 200 are prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF3 including a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the dielectric layer 500 and the dielectric layer 600, and which is considered as a bonding interface of the dielectric layer 500 and the dielectric layer 600. However, the disclosure is not limited thereto, the bonding interface IF3 may include an ‘inorganic dielectric’-to-‘inorganic dielectric’ bonding interface, an ‘inorganic dielectric’-to-‘organic dielectric’ bonding interface, or an ‘organic dielectric’-to-‘organic dielectric’bonding interface.

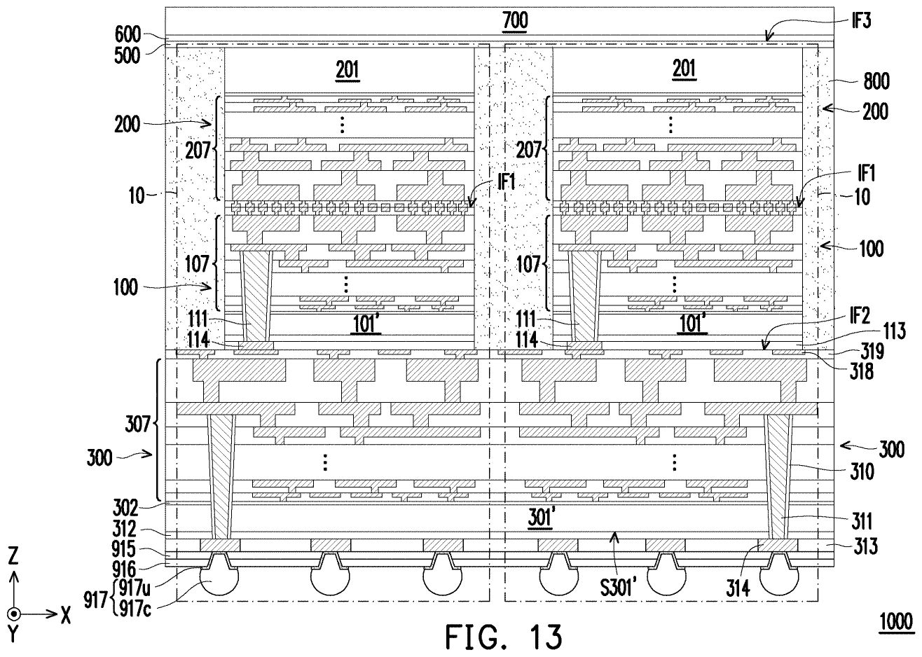

For a non-limiting example, as the material of the carrier 700 is a Si substrate, the carrier 700 may serve as a heat dissipating element for the semiconductor device (e.g., 1000 depicted in FIG. 13). In such embodiments, the carrier 700 may further be used for warpage control. For another non-limiting example, the carrier 700 may be a mechanical supporting structure, which may not be removed after the manufacturing method of the semiconductor structure. For another non-limiting example, as the carrier 700 is a glass carrier, the carrier 700 may be then removed during or after the manufacture of the semiconductor device (e.g., 1000A depicted in FIGS. 14 and/or 1000B depicted in FIG. 15).

The material of the dielectric layer 600 may be any material suitable for bonding and/or debonding the carrier 700 from the above or underlying layer(s) or wafer(s). In some embodiments, the dielectric layer 600 is a blanket layer of dielectric material made of a nitride such as silicon nitride, an oxide such as silicon oxide, oxynitride such as silicon oxynitride, or the like. Alternatively, the dielectric layer 600 may include a dielectric material layer made of a dielectric material including any suitable polymer-based dielectric material (such as BCB, PBO, or the like). Alternatively, the dielectric layer 600 may include a dielectric material layer made of an epoxy-based thermal-release material, which loses its adhesive property when heated, such as a light-to-heat-conversion (LTHC) release coating film. Alternatively, the dielectric layer 600 may include a dielectric material layer made of an ultra-violet (UV) glue, which loses its adhesive property when exposed to UV lights. In some embodiments, the dielectric layer 600 is dispensed over the carrier 700 as a liquid and cured, or is a laminate film laminated onto the carrier 700, or may be the like. A surface of the dielectric layer 600, which is facing away from the carrier 700, may be level and may have a high degree of coplanarity.

Referring to FIG. 13, in some embodiments, a fourth planarization process is performed on the wafer W3 so to thin down the substrate 301 to form a substrate 301′ accessibly reveal the through vias 311 and the liners 310 laterally covering the through vias 311, where a dielectric layer 312 is formed over the substrate 301′ and laterally covering the through vias 311 and the liners 310 protruding out of a surface S301′ of the substrate 301′. The formation and material of the dielectric layer 312 are similar to or substantially identical to the formation and material of the dielectric layer 112 as previously discussed in FIG. 5, and the details (e.g., positioning configurations or the like) between the substrate 301′, the dielectric layer 312, the through vias 311 and the liners 310 are similar to or substantially identical to the details (e.g., positioning configurations or the like) between the substrate 101′, the dielectric layer 112, the through vias 111 and the liners 110 as previously discussed in FIG. 5, and thus are not repeated herein for brevity.

In some embodiments, after forming the dielectric layer 312, a dielectric layer 313 and a plurality of connecting structures 314 are formed on the dielectric layer 312, where at least some of the connecting structures 314 are electrically coupled to the through vias 311, as shown in FIG. 13. For example, the connecting structures 314 are electrically coupled to the stacking units 50 by the through vias 311, the interconnect 307 and the connecting structures 318. In other words, the semiconductor die 300 (e.g., formed in a respective one device region DR3) is electrically coupled to and electrically communicated to the semiconductor dies 100 and 200 of a respective stacking unit 50 disposed thereon. In the cases, the semiconductor die 300 (e.g., formed in a respective one device region DR3) is electrically independent from (e.g., electrically isolated from) the semiconductor dies 100 and 200 of the stacking units 50 disposed on rest of the semiconductor dies 300 (e.g., formed in rest of the device regions DR3). The details, formation and material of the dielectric layers 313 and the connecting structures 314 are similar to or substantially identical to the details, formation and material of the dielectric layers 313 and the connecting structures 314 as previously discussed in FIG. 6, and thus are not repeated herein for brevity.

Continued on FIG. 13, after the formation of the dielectric layer 313 and the connecting structures 314, a dielectric layer 915, a dielectric layer 916 and a plurality of conductive terminals 917 are sequentially formed over the dielectric layer 313 and the connecting structures 314, where the conductive terminals 917 are disposed on and electrically coupled to the connecting structures 314. As shown in FIG. 13, the dielectric layer 915 may be formed on the dielectric layer 313 and the connecting structures 314, and a plurality of first opening (not labeled) formed in and penetrating through the dielectric layer 915 may accessibly reveal some of the connecting structures 314. The dielectric layer 915 may be referred to as a passivation layer. In such cases, the dielectric layer 916 is formed on the dielectric layer 915, and a plurality of second opening (not labeled) formed in and penetrating through the dielectric layer 916 accessibly reveal some of the connecting structures 314 accessibly revealed by the dielectric layer 915. The dielectric layer 916 may be referred to as a post-passivation layer. In some embodiments, the dielectric layer 915 may be a silicon oxide layer, a silicon nitride layer, a silicon oxy-nitride layer or a dielectric layer formed by other suitable dielectric materials, and may be formed by deposition, such as CVD (e.g., PECVD) or the like. The disclosure is not limited thereto. For example, in some embodiments, the dielectric layer 916 may be a PI layer, a PBO layer, or a dielectric layer formed by other suitable polymers, and may be formed by spin-coating or deposition.

In some embodiments, the conductive terminals 917 each may include an under-ball metallurgy (UBM) pattern 917u and a conductive element 917c disposed thereon and electrically coupled thereto. As shown in FIG. 13, the conductive elements 917c of the conductive terminals 917 are electrically coupled to the connecting structures 314 through the UBM patterns 917u of the conductive terminals 917, for example. In the cases the conductive terminals 917 penetrate through the dielectric layer 915 and the dielectric layer 916 to electrically couple to the connecting structures 314.

Each of the UBM patterns 917u, for example, includes a metal layer, which may include a single layer or a composite layer comprising a plurality of sub-layers formed of different materials. In some embodiments, the material of the UBM patterns 917u includes copper, nickel, titanium, molybdenum, tungsten, titanium nitride, titanium tungsten, or alloys thereof or the like, and may be formed by an electroplating process, for example. The UBM patterns 917u each may include titanium layer and a copper layer over the titanium layer. In some embodiments, the UBM patterns 917u are formed using, for example, sputtering, PVD, or the like. The shape and number of the UBM patterns 917u are not limited in the disclosure. Each of the conductive elements 917c, for example, includes micro-bumps, metal pillars, controlled collapse chip connection (C4) bumps (for example, which may have, but not limited to, a size of about 80 μm), a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like. The disclosure is not limited thereto. The shape and number of the conductive elements 917c are not limited in the disclosure.

Continued on FIG. 13, in some embodiments, after forming the conductive terminals 917, a dicing (singulation) process is performed to cut through the dielectric layer 915, the dielectric layer 916, the wafer W3, the insulating encapsulation 800, the dielectric layer 500, the dielectric layer 600 and the carrier 700 to form a plurality of semiconductor devices 1000 each including a plurality of stacking structures 10. Up to here, the semiconductor device 1000 is manufactured. In FIG. 13, only one semiconductor device 1000 is shown for illustrative purposes and simplicity. In a non-limiting example, as shown in the semiconductor device 1000 of FIG. 13, each of the stacking structures 10 includes the semiconductor die 300, the semiconductor die 200, the semiconductor die 100 interposed between and electrically coupling the semiconductor dies 300 and 200, the insulating encapsulation 800 laterally covering the semiconductor dies 100 and 200 and covering the semiconductor die 300 exposed by the semiconductor dies 100 and 200, the carrier 700 disposed on the semiconductor die 200, the dielectric layer 500 disposed between the carrier 700 and the semiconductor die 200 and the between the carrier 700 and the insulating encapsulation 800, the dielectric layer 600 disposed between and bonding the carrier 700 and the dielectric layer 500, the conductive terminals 917 disposed on and electrically coupled to the semiconductor die 300, the dielectric layer 915 disposed between the semiconductor die 300 and the conductive terminals 917, and the dielectric layer 916 disposed between the dielectric layer 915 and the conductive terminals 917. In some embodiments, for each stacking structure 10 included in the semiconductor device 1000, the conductive terminals 917 are electrically coupled to the semiconductor die 300 through the connecting structures 314, some of the conductive terminals 917 are electrically coupled to the semiconductor die 100 through the connecting structures 314, the through vias 311, the interconnect 307, some of the connecting structures 318 and the connecting structures 114, and some of the conductive terminals 917 are electrically coupled to the semiconductor die 200 through the connecting structures 314, the through vias 311, the interconnect 307, some of the connecting structures 318 and the connecting structures 114, the through vias 111, the interconnect 107, the connecting structures 108, and the connecting structures 208. In some embodiments, the stacking structures 10 included in one single semiconductor device 1000 are electrically independent from (e.g., electrically isolated from) each other.

In some embodiments, the semiconductor die 100 included in each stacking structure 10 of the semiconductor device 1000 includes the substrate 101′, the device layer 102, the interconnect 107, the connecting structures 108, the dielectric layer 109, the liners 110, the through vias 111, the dielectric layer 112, the dielectric layer 113 and the connecting structures 114. In some embodiments, the semiconductor die 200 included in each stacking structure 10 of the semiconductor device 1000 includes the substrate 201, the device layer 202, the interconnect 207, the connecting structures 208, and the dielectric layer 209. In some embodiments, the semiconductor die 300 included in each stacking structure 10 of the semiconductor device 1000 includes the substrate 301′, the device layer 302, the interconnect 307, the connecting structures 318, the dielectric layer 319, the liners 310, the through vias 311, the dielectric layer 312, the dielectric layer 313 and the connecting structures 314.

In some embodiments, the semiconductor device 1000A of FIG. 14 is similar to the semiconductor device 1000 of FIG. 13, and the difference is that the carrier 700 and the dielectric layer 600 are removed, where an illustrated top surface S500 of the dielectric layer 500 is exposed. In some embodiments, the semiconductor device 1000B of FIG. 15 is similar to the semiconductor device 1000 of FIG. 13, and the difference is that the carrier 700, the dielectric layer 600 and the dielectric layer 500 are removed, where the illustrated top surface S800 of the insulating encapsulation 800 and the surfaces S201 of the semiconductor dies 200 are exposed.

In some embodiments, in the stacking structure 10 of the semiconductor device 1000, on the X-Y plane (e.g., the top (or plane) view), the size of the semiconductor die 100 and the size of the semiconductor die 200 are substantially identical to each other and are less than the size of the semiconductor die 300 overlapped therewith. In alternative embodiments, in the stacking structure 10 of the semiconductor device 1000, on the X-Y plane (e.g., the top (or plane) view), the size of the semiconductor die 100 and the size of the semiconductor die 200 are substantially identical to each other and are greater than the size of the semiconductor die 300 overlapped therewith. In further alternative embodiments, in the stacking structure 10 of the semiconductor device 1000, on the X-Y plane (e.g., the top (or plane) view), the size of the semiconductor die 100 and the size of the semiconductor die 200 are substantially identical to each other and are substantial equal to the size of the semiconductor die 300 overlapped therewith.

On the other hand, in the semiconductor device 1000, on the X-Y plane (e.g., the top (or plane) view), the size of the semiconductor die 100 in each stacking structure 10 is substantially identical to each other, for example. Alternatively, in the semiconductor device 1000, on the X-Y plane (e.g., the top (or plane) view), the size of the semiconductor die 100 in one stacking structure 10 is substantially identical to the sizes of the semiconductor dies 100 included in some of the stacking structures 10 and is different from the sizes of the semiconductor dies 100 included in rest of the stacking structures 10. Or alternatively, in the semiconductor device 1000, on the X-Y plane (e.g., the top (or plane) view), the size of the semiconductor die 100 in each stacking structure 10 is different from to each other. For a non-limiting example, in the semiconductor device 1000, on the X-Y plane (e.g., the top (or plane) view), the size of the semiconductor die 200 in each stacking structure 10 is substantially identical to each other, for example. Alternatively, in the semiconductor device 1000, on the X-Y plane (e.g., the top (or plane) view), the size of the semiconductor die 200 in one stacking structure 10 is substantially identical to the sizes of the semiconductor dies 200 included in some of the stacking structures 10 and is different from the sizes of the semiconductor dies 200 included in rest of the stacking structures 10. Or alternatively, in the semiconductor device 1000, on the X-Y plane (e.g., the top (or plane) view), the size of the semiconductor die 200 in each stacking structure 10 is different from to each other. For a non-limiting example, in the semiconductor device 1000, on the X-Y plane (e.g., the top (or plane) view), the size of the semiconductor die 300 in each stacking structure 10 is substantially identical to each other, for example. Alternatively, in the semiconductor device 1000, on the X-Y plane (e.g., the top (or plane) view), the size of the semiconductor die 300 in one stacking structure 10 is substantially identical to the sizes of the semiconductor dies 300 included in some of the stacking structures 10 and is different from the sizes of the semiconductor dies 300 included in rest of the stacking structures 10. Or alternatively, in the semiconductor device 1000, on the X-Y plane (e.g., the top (or plane) view), the size of the semiconductor die 300 in each stacking structure 10 is different from to each other.

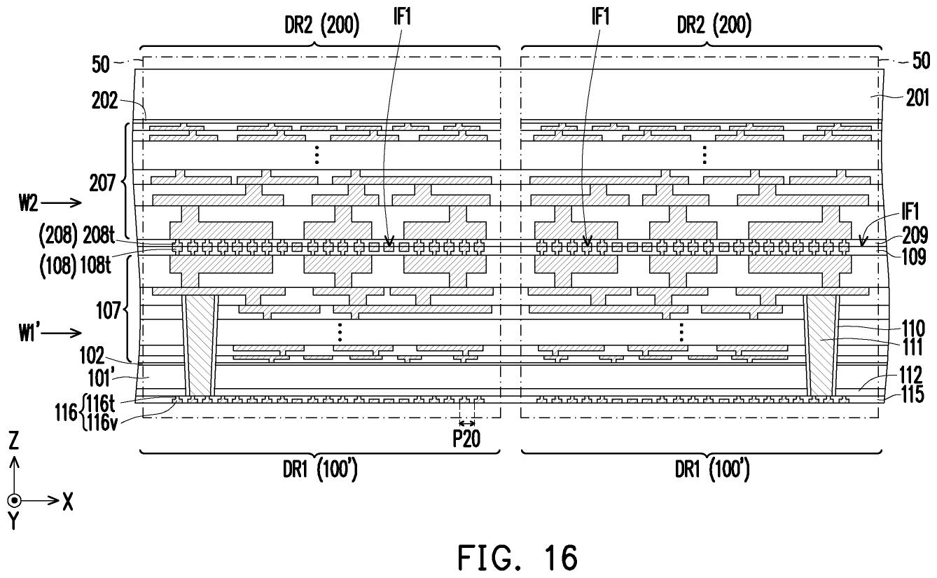

FIG. 16 to FIG. 18 are schematic plane or cross-sectional views of various stages in a manufacturing method of a semiconductor device 2000 in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 16, in some embodiments, a dielectric layer 115 and a plurality of connecting structures 116 are formed on the through vias 111 and the dielectric layer 112, following the process as described in FIG. 5. A pitch P20 between two immediately adjacent connecting structures 116 is less than 1 μm and greater than 0 μm, in some embodiments. The pitch P20 may be greater than 0 μm and may be less than or substantially equal to 0.95 μm or less, 0.90 μm or less, 0.85 μm or less, 0.80 μm or less, 0.75 μm or less, 0.70 μm or less, 0.65 μm or less, 0.60 μm or less, 0.55 μm or less, 0.50 μm or less, 0.45 μm or less, 0.40 μm or less, 0.35 μm or less, 0.30 μm or less, 0.25 μm or less, 0.20 μm or less, 0.15 μm or less, 0.10 μm or less, or so on. The pitches P20 may be less than, greater than, or substantially equal the pitches P1 and P2, the disclosure is not limited thereto. In some embodiments, the pitches P20 is less than the pitches P3 and P10. The details, formation and materials of each of the dielectric layer 115 and the connecting structures 116 (including line portions 116t and via portions 116v) are similar to or substantially identical to the details, formation and materials of each of the dielectric layer 109 and the connecting structures 108 (including 108t and 108v) as previously discussed in FIG. 1, and thus are not repeated herein for brevity. It is appreciated that, each device region RD1 of the wafer W1′ depicted in FIG. 16 is or includes one semiconductor die (or chip) 100′. The sizes, shapes, and types of the semiconductor dies 100′ are similar to or substantially identical to the sizes, shapes, and types of the semiconductor dies 100 previously discussed in FIG. 1, and thus are not repeated herein.

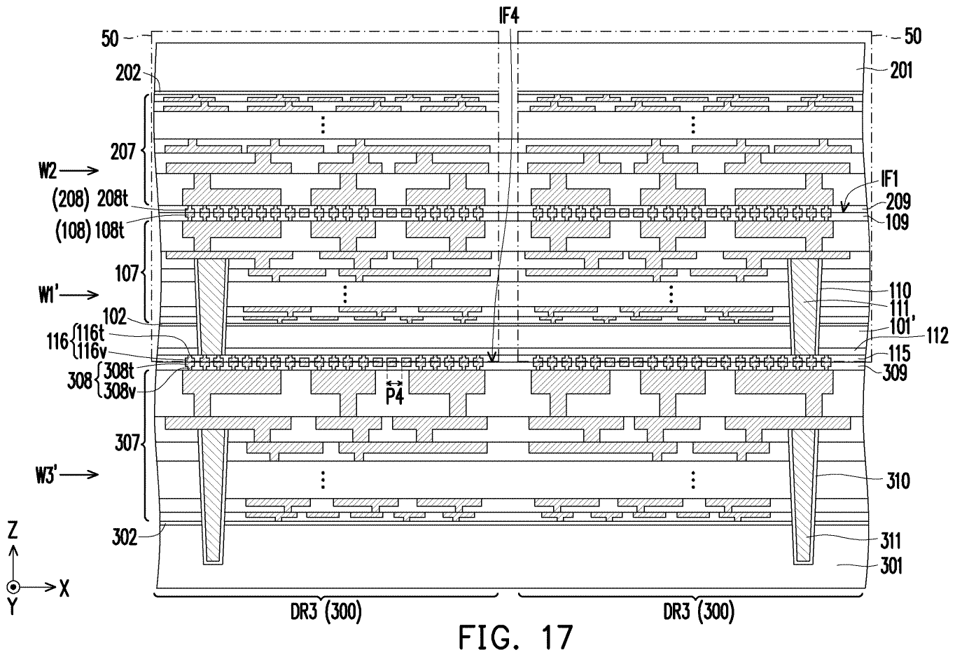

Referring to FIG. 17, in some embodiments, a wafer W3′ is provided. The wafer W3′ is similar to the wafer W3, except that, the dielectric layer 319 and the connecting structures 318 are substituted by a dielectric layer 309 and a plurality of the connecting structures 308. A pitch P4 between two immediately adjacent connecting structures 308 is less than 1 μm and greater than 0 μm, in some embodiments. The pitch P4 may be greater than 0 μm and may be less than or substantially equal to 0.95 μm or less, 0.90 μm or less, 0.85 μm or less, 0.80 μm or less, 0.75 μm or less, 0.70 μm or less, 0.65 μm or less, 0.60 μm or less, 0.55 μm or less, 0.50 μm or less, 0.45 μm or less, 0.40 μm or less, 0.35 μm or less, 0.30 μm or less, 0.25 μm or less, 0.20 μm or less, 0.15 μm or less, 0.10 μm or less, or so on. The pitches P4 may be less than, greater than, or substantially equal the pitches P1, P2 and P20, the disclosure is not limited thereto. In some embodiments, the pitches P4 is less than the pitches P3 and P10. The details, formation and materials of each of the dielectric layer 309 and the connecting structures 308 (including line portions 308t and via portions 308v) are similar to or substantially identical to the details, formation and materials of each of the dielectric layer 109 and the connecting structures 108 (including 108t and 108v) as previously discussed in FIG. 1, and thus are not repeated herein for brevity. It is appreciated that, each device region RD3 of the wafer W3′ depicted in FIG. 17 is or includes one semiconductor die (or chip) 300′. The sizes, shapes, and types of the semiconductor dies 300′ are similar to or substantially identical to the sizes, shapes, and types of the semiconductor dies 300 previously discussed in FIG. 7, and thus are not repeated herein.

In some embodiments, the structure depicted in FIG. 16 is placed over and bonded to the wafer W3′ by bonding process, as shown in FIG. 17. The bonding process is referred to as a WoW bonding process. For example, the wafer W1′ of the structure depicted in FIG. 16 is bonded to the wafer W3′ by bonding process including both of a metal-to-metal bonding and a dielectric-to-dielectric bonding. For example, the wafer W1′ is disposed on (e.g., in physical contact with) and electrically connected to the wafer W3′. In some embodiments, as shown in FIG. 17, the connecting structures 116 of the wafer W1′ and the connecting structures 308 of the wafer W3′ prop against each other and are bonded together through direct metal-to-metal bonding (e.g., such as a ‘copper’-to-‘copper’ bonding). In addition, as shown in FIG. 17, the dielectric layer 115 of the wafer W1′ and the dielectric layer 309 of the wafer W3′ prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF4 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the wafer W2 and the wafer W1, and which is considered as a bonding interface of the wafer W1′ and the wafer W3′.

It should be noted that bonding methods described above are merely examples and are not intended to be limiting. An offset may present between sidewalls of the connecting structures 116 and sidewalls of the connecting structures 308 respectively underlying thereto. Since one of the connecting structures 116 and the connecting structures 308 may have a larger bonding surface than the other one, the direct metal-to-metal bonding may still be achieved even if misalignment occurs, thereby the reliability of electrical connections between the wafer W1′ and the wafer W3′ can be ensured. With such, for certain embodiments, either the dielectric layer 115 immediately adjacent to the connecting structures 116 is bonded to the connecting structures 308 (e.g., a ‘dielectric’-to-‘metal’ bonding), or the dielectric layer 309 immediately adjacent to the connecting structures 308 is bonded to the connecting structures 116 (e.g., a ‘dielectric’-to-‘metal’ bonding). Owing to the connecting structures 116 (with the pitches P20) and the connecting structures 308 (with the pitches P4), the overall routing density of the semiconductor device 2000 is further greatly improved, thereby obtaining higher performance and reduced manufacturing cost.

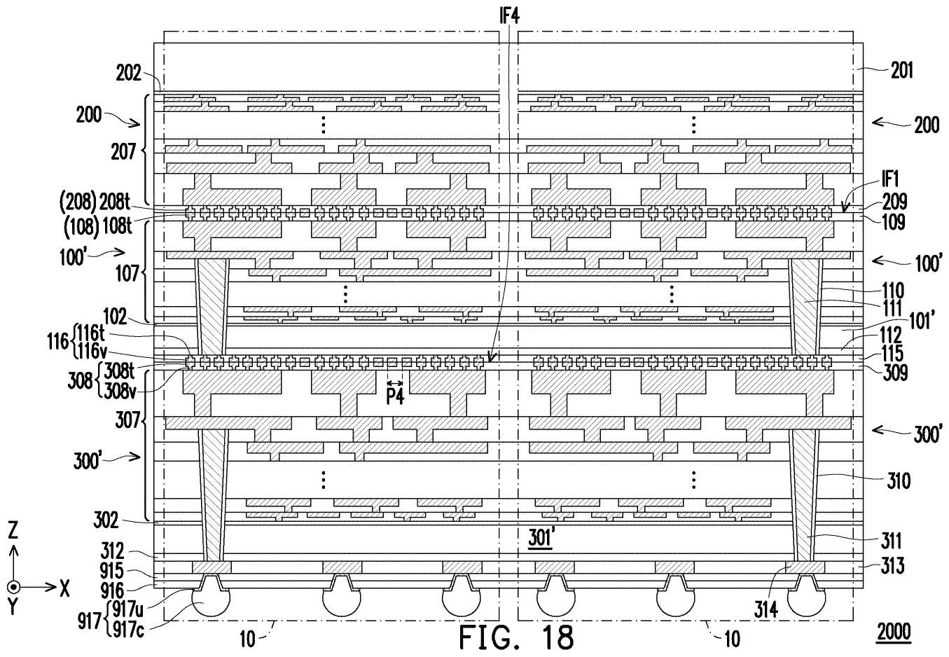

Referring to FIG. 18, in some embodiments, the processes described in FIG. 13 is performed on the structure depicted in FIG. 17 to form a plurality of semiconductor devices 2000. In FIG. 18, only one semiconductor device 2000 is shown for illustrative purposes and simplicity. In a non-limiting example, as shown in the semiconductor device 2000 of FIG. 18, each of the stacking structure 10 includes the semiconductor die 300′, the semiconductor die 200, the semiconductor die 100′ interposed between and electrically coupling the semiconductor dies 300′ and 200, the insulating encapsulation 800 laterally covering the semiconductor dies 100′ and 200 and covering the semiconductor die 300′ exposed by the semiconductor dies 100 and 200, the conductive terminals 917 disposed on and electrically coupled to the semiconductor die 300′, the dielectric layer 915 disposed between the semiconductor die 300′ and the conductive terminals 917, and the dielectric layer 916 disposed between the dielectric layer 915 and the conductive terminals 917. In some embodiments, for each stacking structure 10 included in the semiconductor device 2000, the conductive terminals 917 are electrically coupled to the semiconductor die 300′ through the connecting structures 314, some of the conductive terminals 917 are electrically coupled to the semiconductor die 100′ through the connecting structures 314, the through vias 311, the interconnect 307, some of the connecting structures 308 and the connecting structures 116, and some of the conductive terminals 917 are electrically coupled to the semiconductor die 200 through the connecting structures 314, the through vias 311, the interconnect 307, some of the connecting structures 308, the connecting structures 116, the through vias 111, the interconnect 107, the connecting structures 108, and the connecting structures 208. In some embodiments, the stacking structures 10 included in one single semiconductor device 2000 are electrically independent from (e.g., electrically isolated from) each other.

In some embodiments, the semiconductor die 100′ included in each stacking structure 10 of the semiconductor device 2000 includes the substrate 101′, the device layer 102, the interconnect 107, the connecting structures 108, the dielectric layer 109, the liners 110, the through vias 111, the dielectric layer 112, the dielectric layer 115 and the connecting structures 116. In some embodiments, the semiconductor die 200 included in each stacking structure 10 of the semiconductor device 2000 includes the substrate 201, the device layer 202, the interconnect 207, the connecting structures 208, and the dielectric layer 209. In some embodiments, the semiconductor die 300′ included in each stacking structure 10 of the semiconductor device 2000 includes the substrate 301′, the device layer 302, the interconnect 307, the connecting structures 308, the dielectric layer 309, the liners 310, the through vias 311, the dielectric layer 312, the dielectric layer 313 and the connecting structures 314. In some embodiments, in the stacking structure 10 of the semiconductor device 2000, on the X-Y plane (e.g., the top (or plane) view), the size of the semiconductor die 100 and the size of the semiconductor die 200 are substantially identical to each other and are further substantially identical to the size of the semiconductor die 300 overlapped therewith.

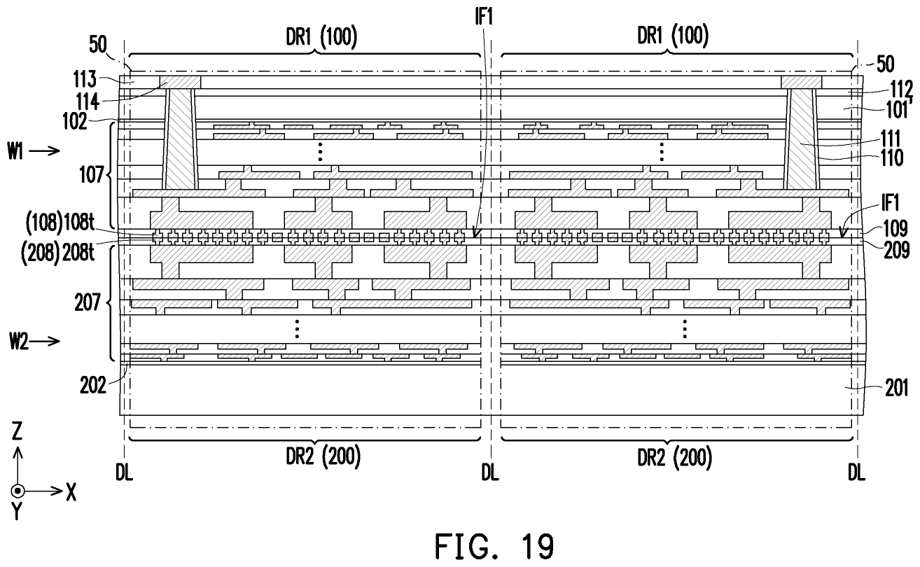

FIG. 19 to FIG. 24 are schematic plane or cross-sectional views of various stages in a manufacturing method of a semiconductor device 3000 in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein. Referring to FIG. 19, in some embodiments, the structure depicted in FIG. 5 is flipped (turned upside down), following the process as described in FIG. 5.

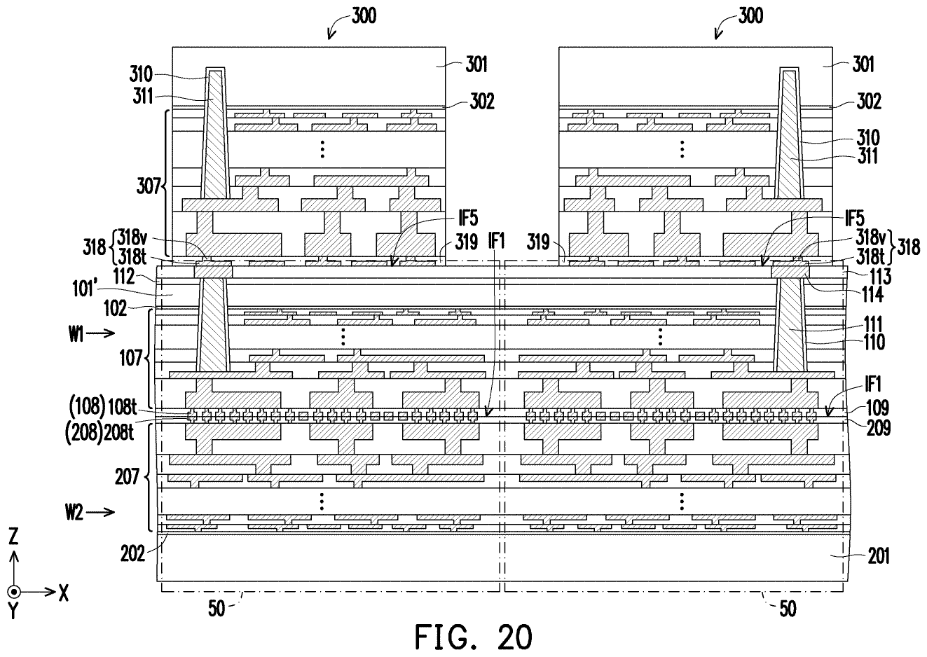

Referring to FIG. 20, in some embodiments, one or more semiconductor dies 300 are picked and placed over the wafer W1. The details of semiconductor dies 300 have been described in FIG. 7, and thus are not repeated herein for brevity. In some embodiments, the semiconductor dies 300 (of a chip-form) are respectively arranged on the stacking units 50 (of the wafer-form), as shown in FIG. 20. For illustrative purposes, only two semiconductor dies 300 are shown in FIG. 20 for simplicity, however the disclosure is not limited thereto. The number of the semiconductor dies 300 may be more than two. The number of the semiconductor dies 300 may be selected and designated based on the demand or design layout. The number of the semiconductor dies 300 may correspond to the number of the stacking units 50. For one non-limiting example, the semiconductor dies 300 are overlapped with the stacking units 50 (of the wafer-form) in a manner of one-to-one configuration, in the direction Z, as shown in FIG. 20. For another non-limiting example, the semiconductor dies 300 are overlapped with the stacking units 50 (of the wafer-form) in a manner of plurality-to-one configuration (such as two-to-one configuration, three-to-one configuration, four-to-one configuration, five-to-one configuration, or the like), in the direction Z.

After the placement of the semiconductor dies 300 (of chip-form), a bonding process is performed to bond the semiconductor dies 300 onto a respective one stacking unit 50 of the wafer-form overlapped therewith along the direction Z, in some embodiments. For example, the semiconductor dies 300 are bonded to the wafer W1 by bonding process including both of a metal-to-metal bonding and a dielectric-to-dielectric bonding. For example, the semiconductor dies 300 are disposed on (e.g., in physical contact with) and electrically connected to the wafer W1. In some embodiments, as shown in FIG. 20, the connecting structures 114 of the semiconductor dies 100 of the wafer W1 and the connecting structures 318 (e.g., 318t) of the semiconductor dies 300 prop against each other and are bonded together through direct metal-to-metal bonding (e.g., such as a ‘copper’-to-‘copper’ bonding). In addition, as shown in FIG. 20, the dielectric layers 113 of the semiconductor dies 100 of the wafer W1 and the dielectric layer 319 of the semiconductor dies 300 prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF5 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the wafer W1 and the semiconductor dies 300, and which is considered as a bonding interface of the wafer W1 and the semiconductor dies 300.

It should be noted that bonding methods described above are merely examples and are not intended to be limiting. An offset may present between sidewalls of the connecting structures 114 and sidewalls of the connecting structures 318 respectively underlying thereto. Since one of the connecting structures 114 and the connecting structures 318 may have a larger bonding surface than the other one, the direct metal-to-metal bonding may still be achieved even if misalignment occurs, thereby the reliability of electrical connections between the wafer W1 and the semiconductor dies 300 can be ensured. With such, for certain embodiments, either the dielectric layer 113 immediately adjacent to the connecting structures 114 is bonded to the connecting structures 318 (e.g., a ‘dielectric’-to-‘metal’ bonding), or the dielectric layer 319 immediately adjacent to the connecting structures 318 is bonded to the connecting structures 114 (e.g., a ‘dielectric’-to-‘metal’ bonding). In the embodiments of which the semiconductor dies 300 are overlapped with the stacking units 50 (of the wafer-form) in a manner of one-to-one configuration, the single semiconductor die 300 overlying each semiconductor die 100 of the wafer W1 is electrically independent from (e.g., electrically isolated from) from each other. In the embodiments of which the semiconductor dies 300 are overlapped with the stacking units 50 (of the wafer-form) in a manner of plurality-to-one configuration, the semiconductor dies 300 overlying a respective one of the semiconductor dies 100 are electrically independent from (e.g., electrically isolated from) the semiconductor dies 300 respectively overlying the rest of the semiconductor dies 100. In some embodiments, the semiconductor dies 300 is bonded to the wafer W1 by CoW bonding.

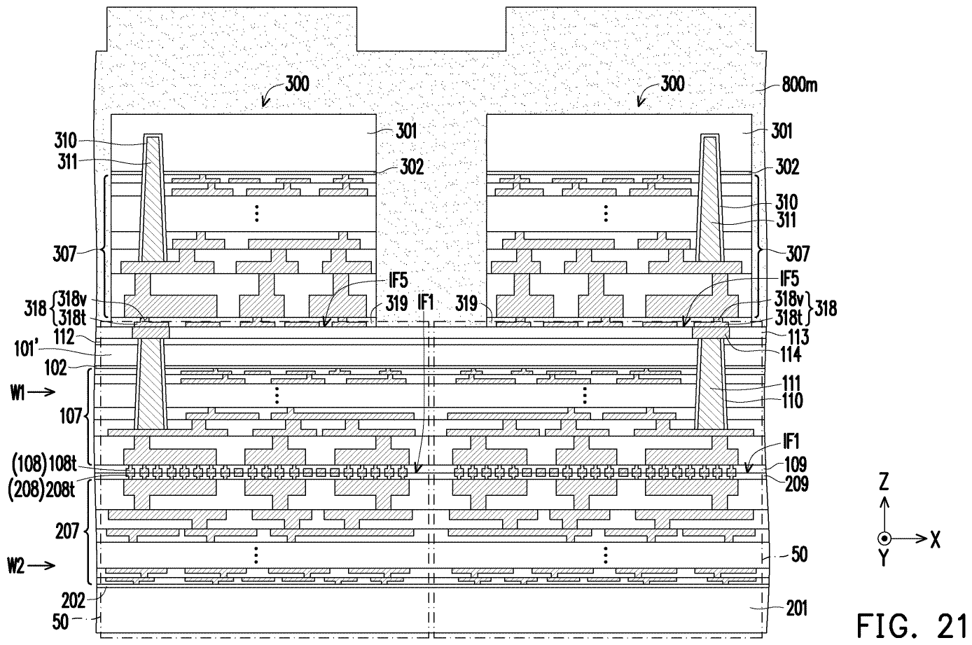

Referring to FIG. 21, in some embodiments, an insulating encapsulation 800m is conformally formed on the semiconductor dies 300 and over the wafer W1, where the semiconductor dies 300 and over the wafer W1 exposed by the semiconductor dies 300 are completely covered by the insulating encapsulation 800m. The formation and material of the insulating encapsulation 800m have been previously described in FIG. 10, and thus are not repeated therein.

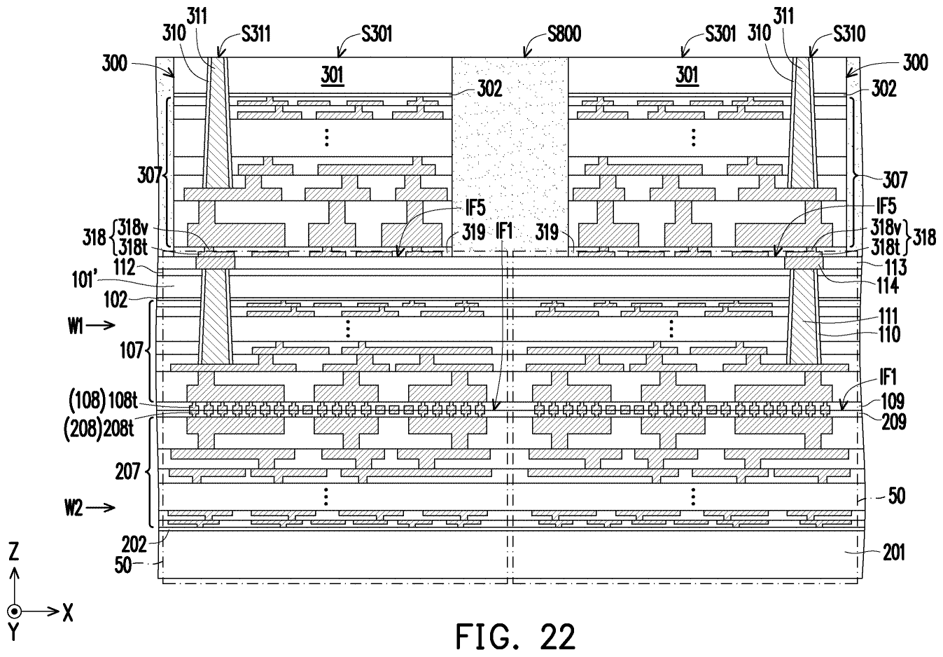

Referring to FIG. 22, in some embodiments, a planarization process is performed on the insulating encapsulation 800m to form an insulating encapsulation 800 exposing the semiconductor dies 300 (e.g., the substrate 301, the through vias 311 and the liners 310). The details of the planarization process is similar to or substantially identical to the planarization process discussed in FIG. 5 and/or the patterning process discussed in FIG. 13, and thus are not repeated therein. For example, the illustrated top surface S800 of the insulating encapsulation 800 is substantially level with the surfaces S301 of the substrate 301, surfaces S311 of the through vias 311 and surfaces S310 of the liners 310. In other words, the illustrated top surface S800 of the insulating encapsulation 800 is substantially coplanar to the surfaces S301 of the substrate 301, the surfaces S311 of the through vias 311 and the surfaces S310 of the liners 310.

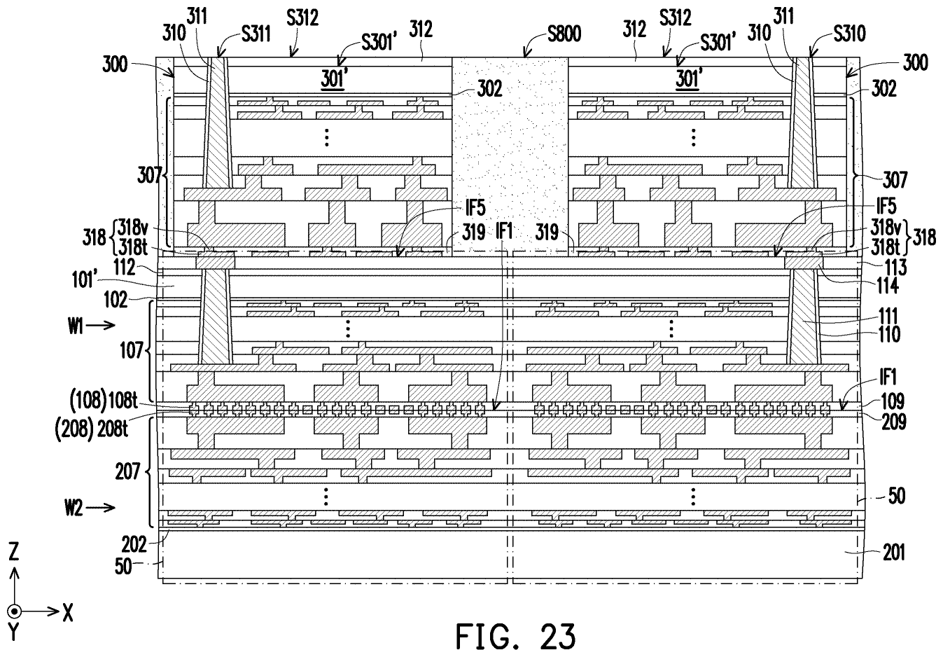

Referring to FIG. 23, in some embodiment, a patterning process is performed on the substrate 301, where the substrate 301 is further partially removed to form a substrate 301′ having a patterned bottom surface S301′, such that a portion of each of the through vias 311 and a portion of each of the liners 310 protrude from the patterned bottom surface S301′ of the substrate 301′. The details of the patterning process is similar to or substantially identical to the patterning process discussed in FIG. 5 and/or the patterning process discussed in FIG. 13, and thus are not repeated therein. As shown in FIG. 23, the liners 310 may cover the entire sidewalls of the through vias 311; however the disclosure is not limited thereto. In one embodiment, the liners 310 may be cover only the sidewalls of the through vias 311 being embedded in the substrate 301′. That is, for example, the liners 310, which are disposed on the sidewalls of the portions of the through vias 311 protruding from the patterned bottom surface S301′ of the substrate 301′ after the planarization process, are removed during the patterning process. After the through vias 311 are protruded out of the substrate 301′, a dielectric layer 312 is formed over the substrate 301′ and laterally cover the through vias 311. The formation and material of the dielectric layer 312 are similar to or substantially identical to the formation and material of the dielectric layer 112 as previously described in FIG. 5 and/or the formation and material of the dielectric layer 312 as previously described in FIG. 13, and thus are not repeated herein. As shown in FIG. 23, a surface S312 of the dielectric layer 312 is substantially level with the bottom surfaces S311 of the through vias 311 and the bottoms surfaces S310 of the liners 310, for example. That is, the surface S312 of the dielectric layer 312 is substantially coplanar to the bottom surfaces S311 of the through vias 311 and the bottoms surfaces S310 of the liners 310.

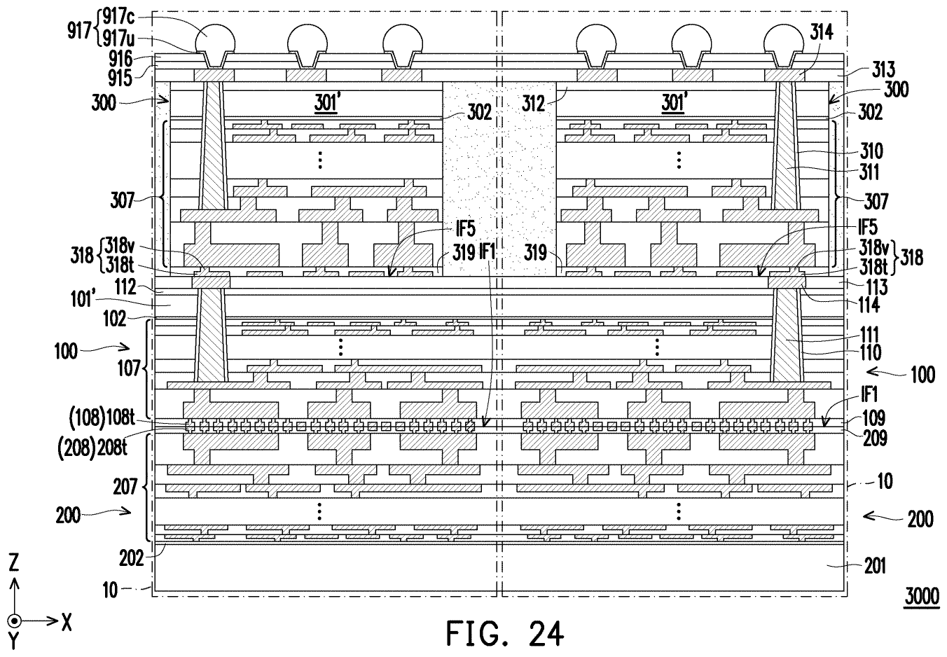

Referring to FIG. 24, in some embodiments, a dielectric layer 313, a plurality of connecting structures 314, a dielectric layer 915, a dielectric layer 916 and a plurality of conductive terminals 917 are sequentially formed over the semiconductor dies 300 and the insulating encapsulation 800 laterally covering the semiconductor dies 300, and a dicing (or singulation) process is performed to form a plurality of semiconductor devices 3000. The formation and material of each of the dielectric layer 313, the connecting structures 314, the dielectric layer 915, the dielectric layer 916 and the conductive terminals 917 have been previously discussed in FIG. 13, and thus are not repeated herein.

In FIG. 24, only one semiconductor device 3000 is shown for illustrative purposes and simplicity. In a non-limiting example, as shown in the semiconductor device 3000 of FIG. 24, each of the stacking structure 10 includes the semiconductor die 300, the semiconductor die 200, the semiconductor die 100 interposed between and electrically coupling the semiconductor dies 300 and 200, the insulating encapsulation 800 laterally covering the semiconductor die 300 and covering the semiconductor die 100 exposed by the semiconductor die 300, the conductive terminals 917 disposed on and electrically coupled to the semiconductor die 300, the dielectric layer 915 disposed between the semiconductor die 300 and the conductive terminals 917, and the dielectric layer 916 disposed between the dielectric layer 915 and the conductive terminals 917. In some embodiments, for each stacking structure 10 included in the semiconductor device 3000, the conductive terminals 917 are electrically coupled to the semiconductor die 300 through the connecting structures 314, some of the conductive terminals 917 are electrically coupled to the semiconductor die 100 through the connecting structures 314, the through vias 311, the interconnect 307, some of the connecting structures 318 and the connecting structures 114, and some of the conductive terminals 917 are electrically coupled to the semiconductor die 200 through the connecting structures 314, the through vias 311, the interconnect 307, some of the connecting structures 318, the connecting structures 314, the through vias 111, the interconnect 107, the connecting structures 108, and the connecting structures 208. In some embodiments, the stacking structures 10 included in one single semiconductor device 3000 are electrically independent from (e.g., electrically isolated from) each other.

In some embodiments, the semiconductor die 100 included in each stacking structure 10 of the semiconductor device 3000 includes the substrate 101′, the device layer 102, the interconnect 107, the connecting structures 108, the dielectric layer 109, the liners 110, the through vias 111, the dielectric layer 112, the dielectric layer 113 and the connecting structures 114. In some embodiments, the semiconductor die 200 included in each stacking structure 10 of the semiconductor device 3000 includes the substrate 201, the device layer 202, the interconnect 207, the connecting structures 208, and the dielectric layer 209. In some embodiments, the semiconductor die 300 included in each stacking structure 10 of the semiconductor device 3000 includes the substrate 301′, the device layer 302, the interconnect 307, the connecting structures 318, the dielectric layer 319, the liners 310, the through vias 311, the dielectric layer 312, the dielectric layer 313 and the connecting structures 314.

In some embodiments, in the stacking structure 10 of the semiconductor device 3000, on the X-Y plane (e.g., the top (or plane) view), the size of the semiconductor die 100 and the size of the semiconductor die 200 are substantially identical to each other and are greater than the size of the semiconductor die 300 overlapped therewith. In alternative embodiments, in the stacking structure 10 of the semiconductor device 3000, on the X-Y plane (e.g., the top (or plane) view), the size of the semiconductor die 100 and the size of the semiconductor die 200 are substantially identical to each other and are less than the size of the semiconductor die 300 overlapped therewith. In further alternative embodiments, in the stacking structure 10 of the semiconductor device 3000, on the X-Y plane (e.g., the top (or plane) view), the size of the semiconductor die 100 and the size of the semiconductor die 200 are substantially identical to each other and are substantial equal to the size of the semiconductor die 300 overlapped therewith.

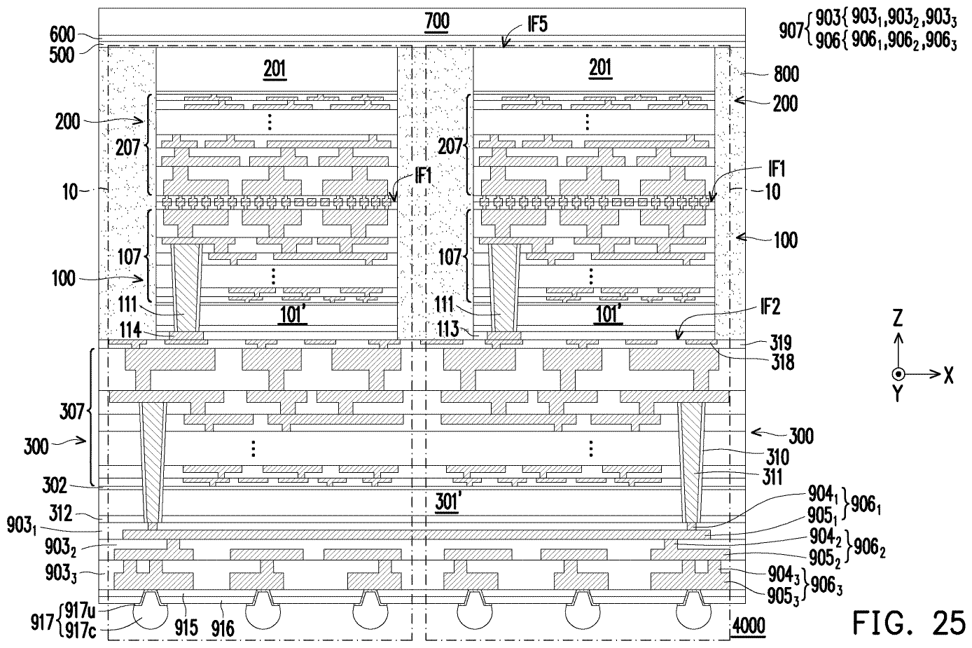

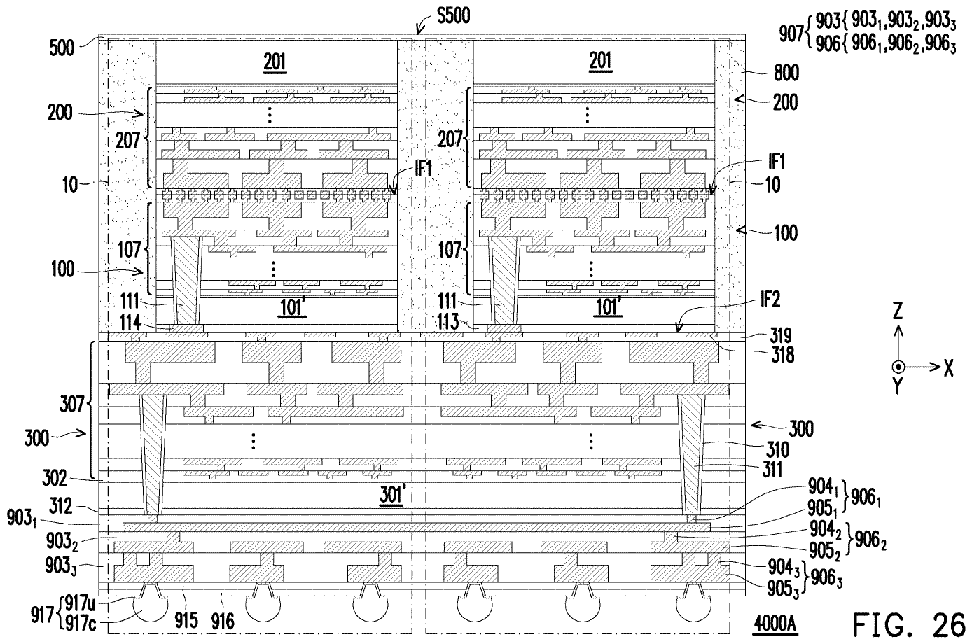

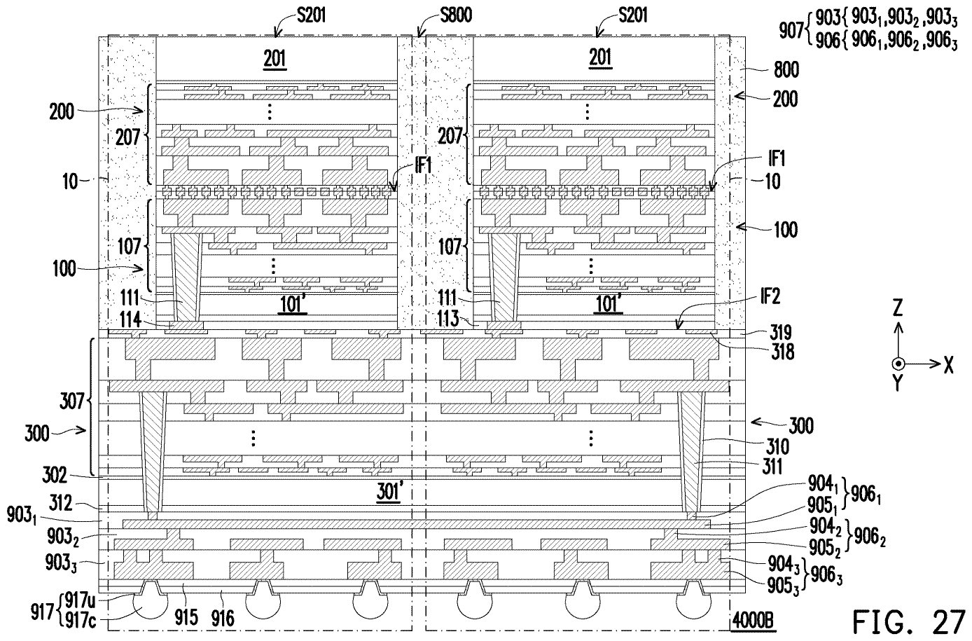

In the embodiments of the semiconductor device 1000, the stacking structures 10 included therein are electrically isolated from each other. However, the disclosure is not limited thereto. FIG. 25 is a schematic cross-sectional view showing a semiconductor device 4000 in accordance with some embodiments of the disclosure. FIG. 26 is a schematic cross-sectional view showing a semiconductor device 4000A in accordance with alternative embodiments of the disclosure. FIG. 27 is a schematic cross-sectional view showing a semiconductor device 4000B in accordance with alternative embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

In some embodiments, the semiconductor device 4000 of FIG. 25 is similar to the semiconductor device 1000 of FIG. 13, and the difference is that, in the semiconductor device 4000, an redistribution circuit structure 907 is included, where the redistribution circuit structure 907 is disposed between and electrically coupled to the through vias 311 and the conductive terminals 917, so that the stacking structures 10 included in the semiconductor device 4000 are electrically coupled to each other through the redistribution circuit structure 907. As shown in FIG. 25, the redistribution circuit structure 907 may be formed after the formation of the dielectric layer 312 and prior to forming the dielectric layer 915. In some embodiments, the redistribution circuit structure 907 is disposed over the through vias 311, the dielectric layer 312 and the insulating encapsulation 800, and the redistribution circuit structure 907 is electrically coupled to the through vias 311 of the semiconductor dies 300. That is, the redistribution circuit structure 907 provides the routing functions to the semiconductor dies 300. In some embodiments, at least some of the semiconductor dies 300 in the semiconductor device 4000 are electrically communicated to one another by the redistribution circuit structure 907. As shown in FIG. 25, the redistribution circuit structure 907 may be overlaid over the semiconductor dies 300 and the insulating encapsulation 800 and includes a plurality of build-up layers being electrically connecting there-between. As shown in FIG. 25, the redistribution circuit structure 907 includes one or more dielectric layers 903 (e.g., 903₁, 903₂, and 903₃) and one or more patterned conductive layers 906 (e.g., 906₁, 906₂, and 906₃). In some embodiments, each patterned conductive layer 906 (e.g., 906₁, 906₂, and 906₃) includes a line portion 905 (e.g., 905₁, 905₂, and 905₃) extending along the horizontal direction (e.g., the direction X or the direction Y), a via portion 904 (e.g., 904₁, 904₂, and 904₃) extending along the vertical direction (e.g., the direction Z), and/or a combination thereof. The patterned conductive layers 906 may be referred to as metallization layers or redistribution layers of the redistribution circuit structure 907 to provide routing functions, and may be collectively referred to as a routing structure of the redistribution circuit structure 907. The dielectric layers 903 may be collectively referred to as a dielectric structure of the redistribution circuit structure 907 to provide protection for the routing structure, the metallization layers or redistribution layers of the redistribution circuit structure 907. In some embodiments, in the redistribution circuit structure 907, the dielectric layers (e.g., 903) and the patterned conductive layers (e.g., 906) are arranged in alternation. One dielectric layer and a respective one metallization layer together may be considered as one build-up layer (e.g., 903₁ and 906₁; 903₂ and 906₂; 903₃ and 906₃; or the like) of the redistribution circuit structure 907. As shown in FIG. 25, for example, a bottommost layer (e.g., 906₃) of the patterned conductive layers 906 may be accessibly revealed by a bottommost layer (e.g., 903₃) of the dielectric layers 903 for external connection (e.g., through the conductive terminals 917). In the disclosure, the numbers of layers of the dielectric layers 903 and the patterned conductive layers 906 are not limited to what is depicted in FIG. 25, and may be selected and designated based on the demand and design layout. That is, the number of layers of the dielectric layers (e.g., 903) and the patterned conductive layers (e.g., 906) independently can be one or greater than one. In some embodiments, line dimensions (e.g., thickness and width) of the patterned conductive layers 906 are gradually increased along a direction from the semiconductor dies 300 to the conductive terminals 917. In some embodiments, the conductive terminals 917 are electrically coupled to the semiconductor dies 300 through the redistribution circuit structure 907.

In addition, one or more seed layers (not shown) may be included in the redistribution circuit structure 907 to facilitate the formation of the patterned conductive layers 906, where the seed layers may be interposed between the patterned conductive layers 906 and the dielectric layers 903. In embodiment of which the seed layers are included, one patterned conductive layer 906 and a respective one seed layer (not shown) may be together referred to as a metallization layer or a redistribution layer of the redistribution circuit structure 907 to provide routing functions. That is, with such embodiments, one patterned conductive layer 906 and a respective one seed layer (not shown) may be collectively referred to as a routing structure of the redistribution circuit structure 907. The formation and material of each of the dielectric layer 903, the patterned conductive layer 906 and the optional seed layer may be similar to or substantially identical to formation and material of each of the dielectric layer 103, the patterned conductive layer 106 and the optional seed layer as previously discussed in FIG. 1, and thus are not repeated herein. Owing to the redistribution circuit structure 907, the horizontal electrical connections between the stacking structures 10 in the semiconductor device 4000 are established.

Similarly, the redistribution circuit structure 907 may be adopted by the semiconductor device 1000A of FIG. 14 (see the semiconductor device 4000A of FIG. 26), the semiconductor device 1000B of FIG. 15 (see the semiconductor device 4000B of FIG. 27), the semiconductor device 2000 of FIG. 18, and the semiconductor device 3000 of FIG. 24. The disclosure is not limited thereto.

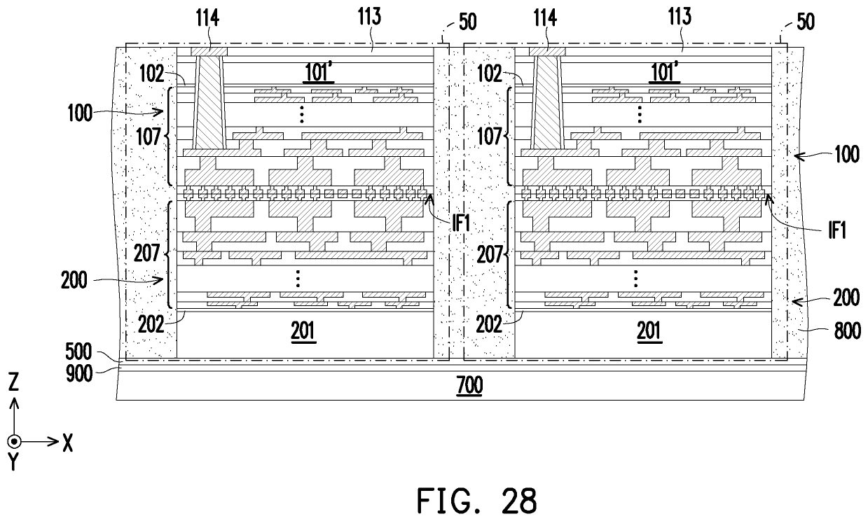

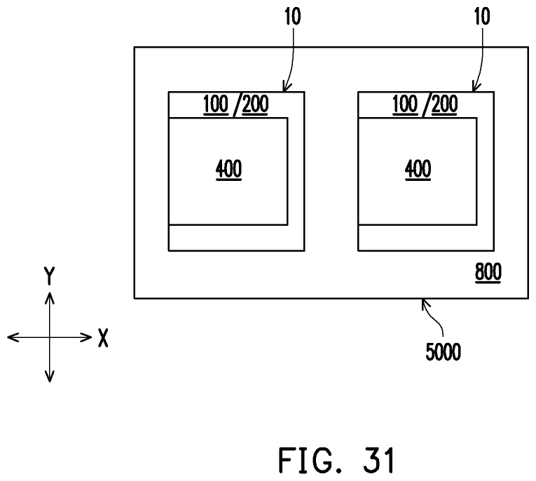

FIG. 28 to FIG. 30 are schematic plane or cross-sectional views of various stages in a manufacturing method of a semiconductor device 5000 in accordance with some embodiments of the disclosure. FIG. 31 to FIG. 33 are schematic plane views of various embodiments of a semiconductor device in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 28, in some embodiments, a carrier 700 coated with a debond layer 900 is provided. The details of the carrier 700 have been described in FIG. 12, and thus are not repeated herein. The material of the debond layer 900 may be any material suitable for bonding and debonding the carrier 700 from the above layer(s) or any wafer(s) disposed thereon. In some embodiments, the debond layer 900 includes a dielectric material layer made of a dielectric material including any suitable polymer-based dielectric material (such as BCB, PBO). For a non-limiting example, the debond layer 900 includes a dielectric material layer made of an epoxy-based thermal-release material, which loses its adhesive property when heated, such as a LTHC release coating film. For another non-limiting example, the debond layer 900 includes a dielectric material layer made of an UV glue, which loses its adhesive property when exposed to UV lights. The debond layer 900 may be dispensed as a liquid and cured on the carrier 700, may be a laminate film laminated onto the carrier 700, or may be formed on the carrier 700 by any suitable method. For example, as shown in FIG. 28, an illustrated top surface of the debond layer 900, which is opposite to an illustrated bottom surface contacting the carrier 700, is leveled and has a high degree of coplanarity. In certain embodiments, the debond layer 900 is a LTHC layer with good chemical resistance, and such layer enables room temperature debonding from the carrier 700 by applying laser irradiation, however the disclosure is not limited thereto.

In an alternative embodiment, a dielectric layer 500 is coated on the debond layer 900, where the debond layer 900 is sandwiched between the dielectric layer 500 and the carrier 700. As shown in FIG. 28, an illustrated top surface of the dielectric layer 500 may further provide a high degree of coplanarity. The details, formation and material of dielectric layer 500 have been described in FIG. 12, and thus are not repeated herein.

In some embodiments, one or more stacking units 50 are picked and placed onto the dielectric layer 500 and over the carrier 700, and an insulating encapsulation 800 is formed to laterally cover the stacking units 50 and cover the dielectric layer 500 exposed by the stacking units 50. As shown in FIG. 28, connecting structures 114 and the dielectric layer 113 are accessibly revealed by the insulating encapsulation 800, for example. The details of the stacking units 50 have been described in FIG. 1 through FIG. 7, the details of the insulating encapsulation 800 have been described in FIG. 10 and FIG. 11, and thus are not repeated herein.

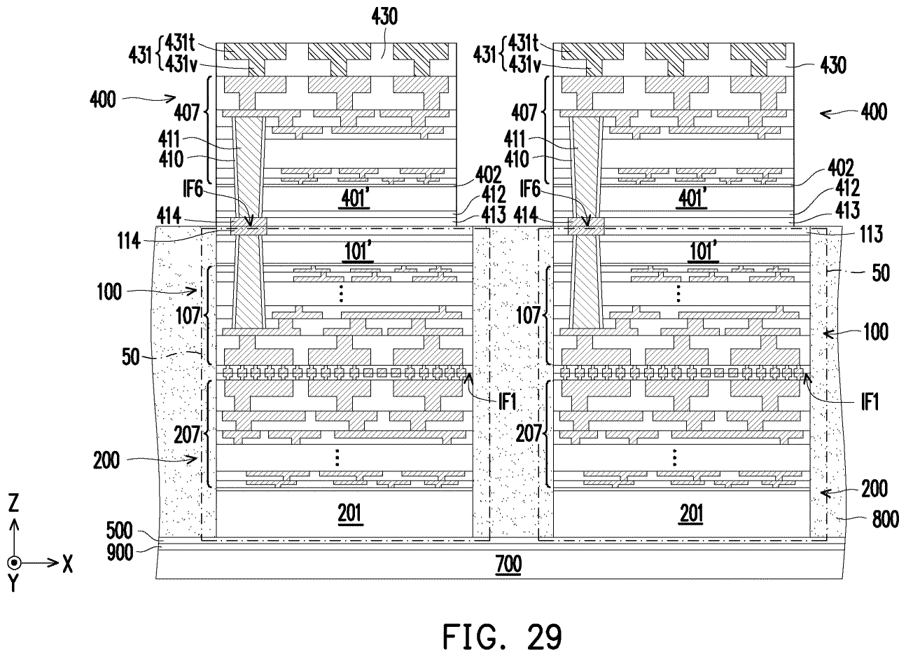

Referring to FIG. 29, in some embodiments, one or more semiconductor dies 400 are picked and placed on the stacking units 50 laterally encapsulated in the insulating encapsulation 800 and over the carrier 700. The semiconductor dies 400 each includes a substrate 401′, a device layer 402 disposed on the substrate 401′, an interconnect 407 (including a plurality of dielectric layers 403 (e.g., 403₁, 403₂, . . . , 403_{N-2}, 403_{N-1}, and 403_{N}) and a plurality of patterned conductive layers 406 (e.g., 406₁, 406₂, . . . , 406_{N-2}, and 406_{N-1}, 406_{N}) each including a line portion 405 (e.g., 405₁, 405₂, . . . , 405_{N-2}, 405_{N-1}, and 405_{N}), a line portion 405 (e.g., 405₁, 405₂, . . . , 405_{N-2}, 405_{N-1}, and 405_{N}) connecting to a via portion 404 (e.g., 404₁, 404₂, . . . , 404_{N-2}, 404_{N-1}, and 404_{N}), and/or a combination thereof) disposed on and electrically coupled to the device layer 402, a dielectric layer 430 disposed on the interconnect 407, a plurality of connecting structures 431 (including a line portion 431t and a via portion 431v) disposed on and electrically coupled to the interconnect 407 and penetrating through the dielectric layer 430, a plurality of through vias 411 embedded in the interconnect 407 and further extending from the interconnect 407 into a position inside the substrate 401′, a plurality of liners 410 lining sidewalls and bottom surfaces of the through vias 411, a dielectric layer 412 disposed on the substrate 401′ and laterally covering the through vias 411 and the liners 410, a dielectric layer 413 disposed on the dielectric layer 412, the through vias 411 and the liners 410, and a plurality of connecting structures 414 penetrating through the dielectric layer 413 and disposed on and electrically coupled to the through vias 411. The formation and materials of each of the substrate 401′, the device layer 402, the interconnect 407 (including 403 and 406 (e.g., 405 and 404), the dielectric layer 430, the liners 410, the through vias 411, the dielectric layer 412, the dielectric layer 413 and the connecting structures 414 of each semiconductor die 400 are similar to the formation and material of each of the substrate 101′, the device layer 102, the interconnect 107 (including 103 and 106 (e.g., 105 and 104), the dielectric layer 109, the liners 110, the through vias 111, the dielectric layer 112, the dielectric layer 113 and the connecting structures 114 of the semiconductor die 100 as previously described in FIG. 1, and thus are not repeated herein. In some embodiments, the connecting structures 414 are aluminum pads or other suitable metal pads, which are formed by deposition and patterning processes, for example. The patterning process may include photolithography and etching process.

For illustrative purposes, only two semiconductor dies 400 are shown in FIG. 29 for simplicity, however the disclosure is not limited thereto. The number of the semiconductor dies 400 may be more than two. The number of the semiconductor dies 400 may be selected and designated based on the demand or design layout. The number of the semiconductor dies 400 may correspond to the number of the stacking units 50. For one non-limiting example, the semiconductor dies 400 are overlapped with the stacking units 50 in a manner of one-to-one configuration, in the direction Z, as shown in FIG. 29. For another non-limiting example, the semiconductor dies 400 are overlapped with the stacking units 50 in a manner of plurality-to-one configuration (such as two-to-one configuration, three-to-one configuration, four-to-one configuration, five-to-one configuration, or the like), in the direction Z.

After the placement of the semiconductor dies 400 (of chip-form), a bonding process is performed to bond the semiconductor dies 400 onto a respective one stacking unit 50 of the chip-form overlapped therewith along the direction Z, in some embodiments. For example, the semiconductor dies 400 are bonded to the semiconductor dies 100 by bonding process including both of a metal-to-metal bonding and a dielectric-to-dielectric bonding. For example, the semiconductor dies 400 are disposed on (e.g., in physical contact with) and electrically connected to the semiconductor dies 100. In some embodiments, as shown in FIG. 29, the connecting structures 114 of the semiconductor dies 100 and the connecting structures 414 of the semiconductor dies 400 prop against each other and are bonded together through direct metal-to-metal bonding (e.g., such as a ‘copper’-to-‘copper’ bonding). In addition, as shown in FIG. 29, the dielectric layers 113 of the semiconductor dies 100 and the dielectric layers 413 of the semiconductor dies 400 prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF6 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the semiconductor dies 100 and the semiconductor dies 400, and which is considered as a bonding interface of the semiconductor dies 100 and the semiconductor dies 400.

It should be noted that bonding methods described above are merely examples and are not intended to be limiting. An offset may present between sidewalls of the connecting structures 114 and sidewalls of the connecting structures 414 respectively underlying thereto. Since one of the connecting structures 114 and the connecting structures 414 may have a larger bonding surface than the other one, the direct metal-to-metal bonding may still be achieved even if misalignment occurs, thereby the reliability of electrical connections between the semiconductor dies 100 and the semiconductor dies 400 can be ensured. With such, for certain embodiments, either the dielectric layer 113 immediately adjacent to the connecting structures 114 is bonded to the connecting structures 414 (e.g., a ‘dielectric’-to-‘metal’ bonding), or the dielectric layer 413 immediately adjacent to the connecting structures 414 is bonded to the connecting structures 114 (e.g., a ‘dielectric’-to-‘metal’ bonding). In the embodiments of which the semiconductor dies 400 are overlapped with the stacking units 50 (of the chip-form) in a manner of one-to-one configuration, the single semiconductor die 400 overlying each semiconductor die 100 is electrically independent from (e.g., electrically isolated from) from each other. In the embodiments of which the semiconductor dies 400 are overlapped with the stacking units 50 (of the chip-form) in a manner of plurality-to-one configuration, the semiconductor dies 400 overlying a respective one of the semiconductor dies 100 are electrically independent from (e.g., electrically isolated from) the semiconductor dies 400 respectively overlying the rest of the semiconductor dies 100. In some embodiments, the semiconductor dies 400 are bonded to the semiconductor dies 100 by chip-on-chip (CoC) bonding.

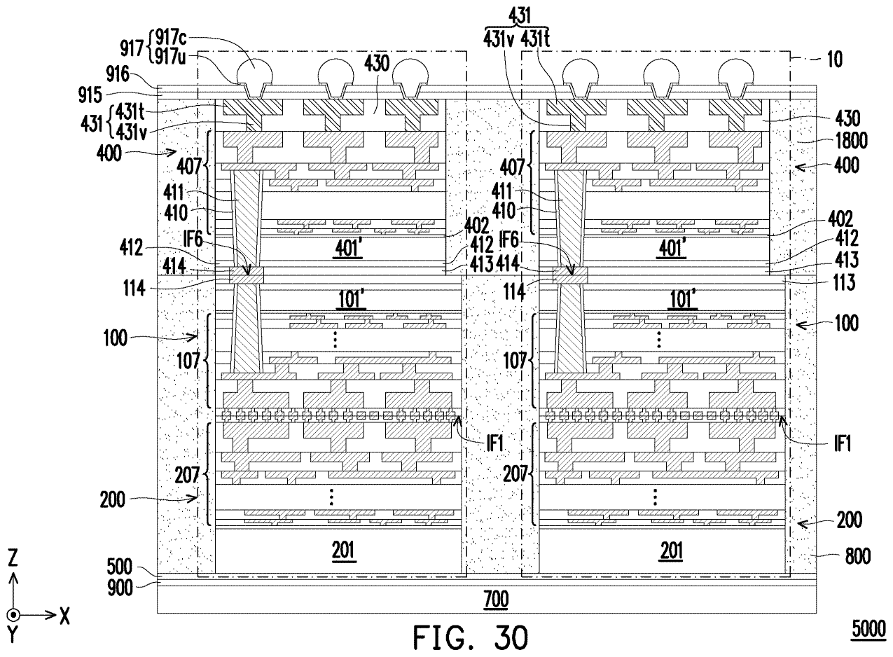

Referring to FIG. 30, in some embodiments, after bonding the semiconductor dies 400 to the semiconductor dies 100, an insulating encapsulation 1800, a dielectric layer 915, a dielectric layer 916 and a plurality of conductive terminals 917 are sequentially formed, and a dicing (or singulation) process is performed to form a plurality of semiconductor devices 5000. The formation and material of the insulating encapsulation 1800 is similar to or substantially identical to the formation and material of the insulating encapsulation 800 as previously discussed in FIG. 10 and FIG. 11, the formation and material of each of the dielectric layer 915, the dielectric layer 916 and the conductive terminals 917 (e.g., 917c and 917u) have been previously discussed in FIG. 13, and thus are not repeated herein. For example, the insulating encapsulation 1800 laterally covers the semiconductor dies 400 and covers the stacking units 50 and the insulating encapsulation 800 exposed by the semiconductor dies 400, where the connecting structures 414 and the dielectric layer 413 of each of the semiconductor dies 400 are accessibly revealed by the insulating encapsulation 1800. In some embodiments, the conductive terminals 917 penetrate through the dielectric layer 915 and the dielectric layer 916 to be electrically coupled to the semiconductor dies 400 by direct contact the connecting structures 414.

In FIG. 30, only one semiconductor device 5000 is shown for illustrative purposes and simplicity. In a non-limiting example, as shown in the semiconductor device 5000 of FIG. 30, each of the stacking structure 10 includes the semiconductor die 400, the semiconductor die 200, the semiconductor die 100 interposed between and electrically coupling the semiconductor dies 400 and 200, the insulating encapsulation 800 laterally covering the semiconductor dies 100 and 200, the insulating encapsulation 1800 laterally covering the semiconductor die 400 and covering the semiconductor die 100 and the insulating encapsulation 800 exposed by the semiconductor die 400, the conductive terminals 917 disposed on and electrically coupled to the semiconductor die 400, the dielectric layer 915 disposed between the semiconductor die 400 and the conductive terminals 917, the dielectric layer 916 disposed between the dielectric layer 915 and the conductive terminals 917, the carrier disposed over the semiconductor die 200, the debond layer 900 are disposed between the carrier 700 and the semiconductor die 200, and the dielectric layer 500 is disposed between the debond layer 900 and the semiconductor die 200. In some embodiments, for each stacking structure 10 included in the semiconductor device 5000, the conductive terminals 917 are electrically coupled to the semiconductor die 400 through the connecting structures 431, some of the conductive terminals 917 are electrically coupled to the semiconductor die 100 through the connecting structures 431, the interconnect 407, the through vias 411, some of the connecting structures 414 and some of the connecting structures 114, and some of the conductive terminals 917 are electrically coupled to the semiconductor die 200 through the connecting structures 431, the interconnect 407, the through vias 411, some of the connecting structures 414 and some of the connecting structures 114, the through vias 111, the interconnect 107, the connecting structures 108, and the connecting structures 208. In some embodiments, the stacking structures 10 included in one single semiconductor device 5000 are electrically independent from (e.g., electrically isolated from) each other.

In some embodiments, the semiconductor die 100 included in each stacking structure 10 of the semiconductor device 5000 includes the substrate 101′, the device layer 102, the interconnect 107, the connecting structures 108, the dielectric layer 109, the liners 110, the through vias 111, the dielectric layer 112, the dielectric layer 113 and the connecting structures 114. In some embodiments, the semiconductor die 200 included in each stacking structure 10 of the semiconductor device 5000 includes the substrate 201, the device layer 202, the interconnect 207, the connecting structures 208, and the dielectric layer 209. In some embodiments, the semiconductor die 400 included in each stacking structure 10 of the semiconductor device 4000 includes the substrate 401′, the device layer 402, the interconnect 407, the connecting structures 431, the dielectric layer 430, the liners 410, the through vias 411, the dielectric layer 412, the dielectric layer 413 and the connecting structures 414.

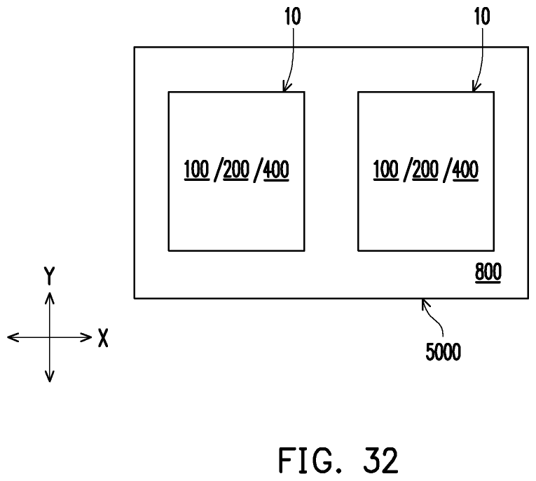

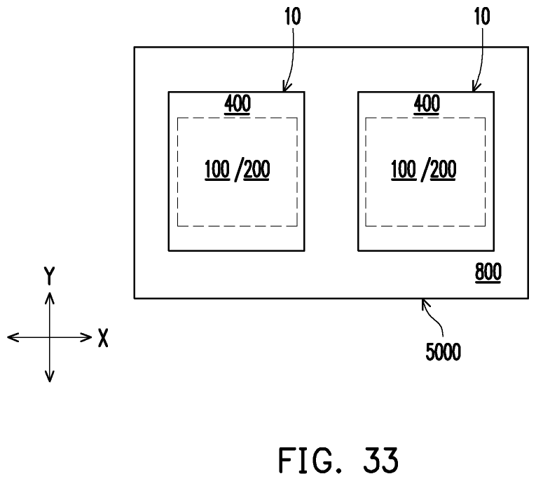

In some embodiments, in the stacking structure 10 of the semiconductor device 5000, on the X-Y plane (e.g., the top (or plane) view depicted in FIG. 31), the size of the semiconductor die 100 and the size of the semiconductor die 200 are substantially identical to each other and are greater than the size of the semiconductor die 400 overlapped therewith. In alternative embodiments, in the stacking structure 10 of the semiconductor device 5000, on the X-Y plane (e.g., the top (or plane) view depicted in FIG. 32), the size of the semiconductor die 100 and the size of the semiconductor die 200 are substantially identical to each other and are substantially equal to the size of the semiconductor die 400 overlapped therewith. In further alternative embodiments, in the stacking structure 10 of the semiconductor device 5000, on the X-Y plane (e.g., the top (or plane) view depicted in FIG. 33), the size of the semiconductor die 100 and the size of the semiconductor die 200 are substantially identical to each other and are less than the size of the semiconductor die 400 overlapped therewith.

Similarly, the redistribution circuit structure 907 may be adopted by the semiconductor device 5000 of FIG. 30. The disclosure is not limited thereto.

In some embodiments, the semiconductor dies 300 and/or 400 and modifications thereof individually may be a memory (such as DRAM). The semiconductor dies 100, 200 and modifications thereof individually may be a logic die. The semiconductor devices 1000, 1000A, 1000B, 2000, 3000, 4000, 4000A, 4000B, 5000 and/or modifications thereof individually may be further mounted onto another electronical component or onto a circuit structure, such as a mother board, a package substrate, a printed circuit board (PCB), a printed wiring board, and/or other carrier that is capable of carrying integrated circuits. Or, the semiconductor devices 1000, 1000A, 1000B, 2000, 3000, 4000, 4000A, 4000B, 5000 and/or modifications thereof may be or may be part of an integrated Fan-Out (InFO) package, an InFO package having a Package-on-Package (PoP) structure, a chip-on-wafer-on-substrate (CoWoS) package, a flip chip package of an InFO package, or the like. The disclosure is not limited thereto. The conductive terminals 917 may be referred to as connectors or terminals of the semiconductor devices 1000, 1000A, 1000B, 2000, 3000, 4000, 4000A, 4000B, 5000 and/or modifications thereof.

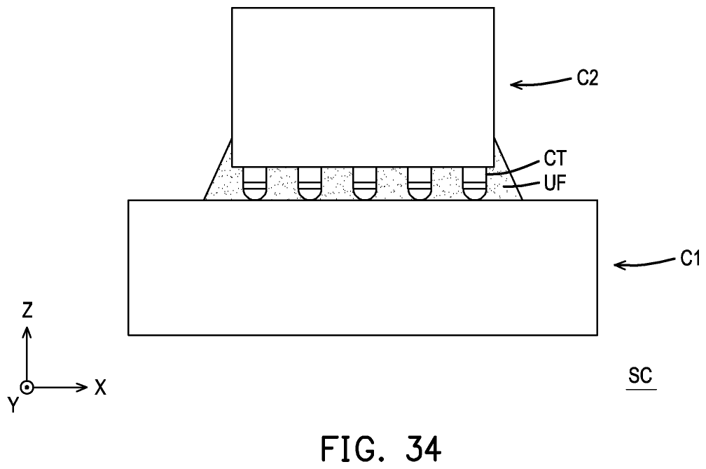

FIG. 34 is a schematic cross-sectional view showing an application of a semiconductor device (e.g., the semiconductor devices 1000, 1000A, 1000B, 2000, 3000, 4000, 4000A, 4000B, 5000 and/or modifications thereof) in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 34, in some embodiments, a component assembly SC including a first component C1 and a second component C2 disposed over the first component C1 is provided. The first component C1 may be or may include a circuit structure, such as a mother board, a package substrate, another printed circuit board (PCB), a printed wiring board, and/or other carrier that is capable of carrying integrated circuits. In some embodiments, the second component C2 mounted on the first component C1 is similar to one of the semiconductor devices 1000, 1000A, 1000B, 2000, 3000, 4000, 4000A, 4000B, 5000 and/or modifications thereof. For example, one or more second components C2 (e.g., 1000, 1000A, 1000B, 2000, 3000, 4000, 4000A, 4000B, 5000 and/or modifications thereof) may be electrically coupled to the first component C1 through a plurality of terminals CT. The terminals CT may be the conductive terminals 917. In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill UF may be formed by underfill dispensing, a capillary flow process, or any other suitable method. Owing to the underfill UF, a bonding strength between the first component C1 and the second component C2 is enhanced.

In accordance with some embodiments, a semiconductor device includes a first die, a second die and a third die. The first die has a first side including a plurality of first connecting structures and a second side including a plurality of second connecting structures, where the first side is opposite to the second side. The second die has a third side including a plurality of third connecting structures, where the plurality of third connecting structures are in contact with the plurality of first connecting structures of the first die. The third die has a fourth side including a plurality of fourth connecting structures, where the plurality of fourth connecting structures are in contact with the plurality of second connecting structures of the first die. A first pitch of the plurality of first connecting structures and a second pitch of the plurality of third connecting structures are less than a third pitch of the plurality of fourth connecting structures.

In accordance with some embodiments, a semiconductor device includes a first stacking structure, a second stacking structure and a plurality of conductive terminals. The first stacking structure and the second stacking structure each includes a first die, a second die, and a third die. The first die has a first side and a second side. The second die is bonded to the first side of the first die via a first bonding interface including a first metal-to-metal bonding interface and a first dielectric-to-dielectric bonding interface. The third die is bonded to the second side of the first die via a second bonding interface including a second metal-to-metal bonding interface and a second dielectric-to-dielectric bonding interface. The first stacking structure is electrically independent from the second stacking structure. The plurality of conductive terminals are disposed over and electrically coupled to the third die of the first stacking structure and the third die of the second stacking structure.

In accordance with some embodiments, a method of manufacturing a semiconductor device includes the following steps: providing a first wafer comprising a fist die, the first die having a first side comprising a plurality of first connecting structures and a second side comprising a plurality of second connecting structures, the first side being opposite to the second side; providing a second wafer comprising a second die, the second die having a third side comprising a plurality of third connecting structures; bonding the first die of the first wafer to the second die of the second wafer, the plurality of third connecting structures being in contact with the plurality of first connecting structures of the first die; providing a third die, the third die having a fourth side comprising a plurality of fourth connecting structures; and bonding the first die to the third die, the plurality of fourth connecting structures being in contact with the plurality of second connecting structures of the first die, wherein a first pitch of the plurality of first connecting structures and a second pitch of the plurality of third connecting structures are less than a third pitch of the plurality of fourth connecting structures.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a first die, having a first side comprising a plurality of first connecting structures and a second side comprising a plurality of second connecting structures, the first side being opposite to the second side;
a second die, having a third side comprising a plurality of third connecting structures, the plurality of third connecting structures being in contact with the plurality of first connecting structures of the first die;
a third die, having a fourth side comprising a plurality of fourth connecting structures, the plurality of fourth connecting structures being in contact with the plurality of second connecting structures of the first die, wherein the third die further comprises:
a substrate;
an interconnect, disposed over the substrate and comprising a plurality of patterned conductive layers and a plurality of dielectric layers being arranged in alternation; and
at least one through via, embedded in and electrically coupled to the interconnect and further extended into the substrate; and
a plurality of conductive terminals, disposed over and electrically coupled to the third die, wherein the first die is between the third die and the second die, and the interconnect is between the plurality of conductive terminals and the first die,
wherein a first pitch of the plurality of first connecting structures and a second pitch of the plurality of third connecting structures are less than a third pitch of the plurality of fourth connecting structures.

2. The semiconductor device of claim 1, wherein a first bonding interface between the plurality of first connecting structures and the plurality of third connecting structures comprising a first metal-to-metal bonding interface and a first dielectric-to-dielectric bonding interface, and a second bonding interface between the plurality of second connecting structures and the plurality of fourth connecting structures comprising a second metal-to-metal bonding interface and a second dielectric-to-dielectric bonding interface.

3. The semiconductor device of claim 1, further comprising:
an insulating encapsulation, laterally covering the first die and the second die, wherein a sidewall of the insulating encapsulation is substantially aligned to a sidewall of the third die.

4. The semiconductor device of claim 1, further comprising:
an insulating encapsulation, laterally covering the third die, wherein a sidewall of the insulating encapsulation is substantially aligned to a sidewall of the first die and a sidewall of the second die.

5. The semiconductor device of claim 1, further comprising:
a first insulating encapsulation, laterally covering the first die and the second die; and
a second insulating encapsulation, laterally covering the third die,
wherein a sidewall of the first insulating encapsulation is substantially aligned to a sidewall of the second insulating encapsulation.

6. The semiconductor device of claim 1, wherein a sidewall of the first die, a sidewall of a second die and a sidewall of third die are substantially aligned with each other.

7. The semiconductor device of claim 1, further comprising:
a redistribution circuit structure, disposed over the third die and electrically coupled thereto, wherein the redistribution circuit structure is disposed between and electrically couples the third die and the plurality of conductive terminals.

8. The semiconductor device of claim 1, wherein the plurality of conductive terminals are disposed on and electrically coupled to a plurality of fifth connecting structures distributed on a fifth side of the third die, the fourth side being opposite to the fifth side, wherein a material of the plurality of fifth connecting structures comprises aluminum.

9. A semiconductor device, comprising:
a first stacking structure and a second stacking structure, each comprising:
a first die, having a first side and a second side;
a second die, bonded to the first side of the first die via a first bonding interface including a first metal-to-metal bonding interface and a first dielectric-to-dielectric bonding interface; and
a third die, bonded to the second side of the first die via a second bonding interface including a second metal-to-metal bonding interface and a second dielectric-to-dielectric bonding interface,
wherein the first stacking structure is electrically independent from the second stacking structure; and
a plurality of conductive terminals, disposed over and electrically coupled to the third die of the first stacking structure and the third die of the second stacking structure.

10. The semiconductor device of claim 9, wherein in a stacking direction of the first die, the second die and the third die, a projection of the first die is substantially equal to a projection of the second die.

11. The semiconductor device of claim 9, wherein the first die of the first stacking structure is connected to the first die of the second stacking structure, the second die of the first stacking structure is connected to the second die of the second stacking structure, and the third die of the first stacking structure is connected to the third die of the second stacking structure.

12. The semiconductor device of claim 9, wherein the first die of the first stacking structure is connected to the first die of the second stacking structure, and the second die of the first stacking structure is connected to the second die of the second stacking structure, and the semiconductor device further comprises:
an insulating encapsulation, laterally covering the third die of the first stacking structure and the third die of the second stacking structure.

13. The semiconductor device of claim 9, wherein the third die of the first stacking structure is connected to the third die of the second stacking structure, and the semiconductor device further comprises:
an insulating encapsulation, laterally covering the first die and the second die of the first stacking structure and the first die and the second die of the second stacking structure.

14. The semiconductor device of claim 9, further comprising:
a first insulating encapsulation, laterally covering the first die and the second die of the first stacking structure and the first die and the second die of the second stacking structure; and
a second insulating encapsulation, laterally covering the third die of the first stacking structure and the third die of the second stacking structure.

15. The semiconductor device of claim 9, further comprising:
a redistribution circuit structure, disposed between the third die of the first stacking structure is connected to the third die of the second stacking structure, wherein the first stacking structure and the second stacking structure are electrically coupled to each other through the redistribution circuit structure.

16. A semiconductor device, comprising:
a first die, having a first side comprising a plurality of first connecting structures and a second side comprising a plurality of second connecting structures, the first side being opposite to the second side;
a second die, having a third side comprising a plurality of third connecting structures, the plurality of third connecting structures being connected to the plurality of first connecting structures of the first die;
a third die, having a fourth side comprising a plurality of fourth connecting structures, the plurality of fourth connecting structures being connected to the plurality of second connecting structures of the first die, wherein the third die further comprises:
a substrate;
an interconnect, disposed over the substrate and comprising a plurality of dielectric layers vertically stacked on one another; and
at least one through via, extending from the interconnect to the substrate, wherein the at least one through via penetrates through one or more of the plurality of dielectric layers and the substrate; and
a plurality of conductive terminals, connected to and electrically coupled to the third die, wherein the first die is between the third die and the second die, and the interconnect is between the plurality of conductive terminals and the first die,
wherein a first pitch of the plurality of first connecting structures and a second pitch of the plurality of third connecting structures are less than a third pitch of the plurality of fourth connecting structures.

17. The semiconductor device of claim 16, further comprising:
an insulating encapsulation, laterally covering the first die and the second die, wherein a sidewall of the insulating encapsulation is substantially aligned to a sidewall of the third die, or
an insulating encapsulation, laterally covering the third die, wherein a sidewall of the insulating encapsulation is substantially aligned to a sidewall of the first die and a sidewall of the second die.

18. The semiconductor device of claim 16, further comprising:
a first insulating encapsulation, laterally covering the first die and the second die; and
a second insulating encapsulation, laterally covering the third die,
wherein a sidewall of the first insulating encapsulation is substantially aligned to a sidewall of the second insulating encapsulation.

19. The semiconductor device of claim 16, wherein a sidewall of the first die, a sidewall of a second die and a sidewall of third die are substantially aligned with each other.

20. The semiconductor device of claim 16, further comprising:
a redistribution circuit structure, disposed over the third die and electrically coupled thereto, wherein the redistribution circuit structure is disposed between and electrically couples the third die and the plurality of conductive terminals.
